(19) United States
(12) Patent Application Publication
(10) Pub. No.: US 2024/0112992 A1
(43) Pub. Date: Apr. 4, 2024

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventor: Isamu NISHIMURA, Kyoto-shi (JP)

(21) Appl. No.: 18/538,641

(22) Filed: Dec. 13, 2023

Related U.S. Application Data
(63) Continuation of application No. PCT/JP2022/023069, filed on Jun. 8, 2022.

(30) Foreign Application Priority Data
Jun. 22, 2021 (JP) 2021-103355

(51) Int. Cl. H01L 23/495; H01L 23/00; H01L 23/31; H01L 25/065

(52) U.S. Cl. CPC H01L 23/49531; H01L 23/3107; H01L 23/4952; H01L 23/49589; H01L 24/16; H01L 24/48; H01L 25/0652; H01L 2224/16146; H01L 2224/16225; H01L 2224/48137; H01L 2224/48227; H01L 2924/014; H01L 2924/0665; H01L 2924/13091; H01L 2924/182

(57) ABSTRACT

A semiconductor device includes a first resin layer having a first obverse surface facing in a thickness direction, a first wiring layer facing the first obverse surface, a semiconductor layer, and a semiconductor element. The semiconductor element includes an electrode electrically connected to the semiconductor layer and facing the first obverse surface and is electrically bonded at the electrode to the first wiring layer. The semiconductor device further includes a second resin layer having a second obverse surface facing the same side as the first obverse surface in the thickness direction, and a second wiring layer facing the second obverse surface and electrically connected to the semiconductor layer. The second wiring layer is in contact with the semiconductor layer. The second wiring layer extends across an outer edge of the semiconductor layer as viewed in the thickness direction.

### TECHNICAL FIELD

The present disclosure relates to a semiconductor device including a semiconductor element with a vertical structure and also to a method for manufacturing such a semiconductor device.

### BACKGROUND ART

WO 2019/203139 A1 discloses an example of a semiconductor device including a semiconductor element (MOSFET) with a vertical structure. In the semiconductor device, an electrode (drain) of the semiconductor element is disposed on one side in the thickness direction and electrically bonded to one of a plurality of leads. Another electrode (source) of the semiconductor element is disposed on the other side in the thickness direction, and a wire is bonded to that electrode. The wire is also bonded to a lead that is different from the one electrically bonded to the semiconductor element. These leads are spaced apart from each other in plan view. Due to this configuration, the semiconductor device tends to be relatively large in plan-view size and have a relatively large parasitic resistance. In view of these, there is still room for improvement.

### BRIEF DESCRIPTION OF THE DRAWINGS

FIG. 1 is a plan view of a semiconductor device according to a first embodiment of the present disclosure, with a third resin layer shown as transparent.

FIG. 2 is a plan view corresponding to FIG. 1, with a second resin layer and a plurality of second wiring layers also shown as transparent.

FIG. 3 is a plan view corresponding to FIG. 2, with a plurality of semiconductor elements, an IC, and a plurality of second pillar wiring layers also shown as transparent.

FIG. 4 is a bottom view of the semiconductor device shown in FIG. 1.

FIG. 5 is a front view of the semiconductor device shown in FIG. 1.

FIG. 6 is a left-side view of the semiconductor device shown in FIG. 1.

FIG. 7 is a sectional view taken along line VII-VII in FIG. 2.

FIG. 8 is a sectional view taken along line VIII-VIII in FIG. 2.

FIG. 9 is a sectional view taken along line IX-IX in FIG. 2.

FIG. 10 is a sectional view taken along line X-X in FIG. 2.

FIG. 11 is an enlarged view showing a portion of FIG. 7 around a semiconductor elements belonging to a group of high-voltage elements.

FIG. 12 is an enlarged view showing a portion of FIG. 7 around a first pillar wiring layer, a second pillar wiring layer, and a terminal.

FIG. 13 is an enlarged view showing a portion of FIG. 11.

FIG. 14 is a sectional view for illustrating a step of manufacturing the semiconductor device shown in FIG. 1.

FIG. 15 is a sectional view for illustrating a step of manufacturing the semiconductor device shown in FIG. 1.

FIG. 16 is a sectional view for illustrating a step of manufacturing the semiconductor device shown in FIG. 1.

FIG. 17 is a sectional view for illustrating a step of manufacturing the semiconductor device shown in FIG. 1.

FIG. 18 is a sectional view for illustrating a step of manufacturing the semiconductor device shown in FIG. 1.

FIG. 19 is a sectional view for illustrating a step of manufacturing the semiconductor device shown in FIG. 1.

FIG. 20 is a sectional view for illustrating a step of manufacturing the semiconductor device shown in FIG. 1.

FIG. 21 is a sectional view for illustrating a step of manufacturing the semiconductor device shown in FIG. 1.

FIG. 22 is a sectional view for illustrating a step of manufacturing the semiconductor device shown in FIG. 1.

FIG. 23 is a sectional view for illustrating a step of manufacturing the semiconductor device shown in FIG. 1.

FIG. 24 is a sectional view for illustrating a step of manufacturing the semiconductor device shown in FIG. 1.

FIG. 25 is a sectional view for illustrating a step of manufacturing the semiconductor device shown in FIG. 1.

FIG. 26 is a sectional view for illustrating a step of manufacturing the semiconductor device shown in FIG. 1.

FIG. 27 is a sectional view for illustrating a step of manufacturing the semiconductor device shown in FIG. 1.

FIG. 28 is a sectional view for illustrating a step of manufacturing the semiconductor device shown in FIG. 1.

FIG. 29 is a sectional view for illustrating a step of manufacturing the semiconductor device shown in FIG. 1.

FIG. 30 is a plan view of a semiconductor device according to a second embodiment of the present disclosure, with a second resin layer, a third resin layer and a plurality of second wiring layers shown as transparent.

FIG. 31 is a front view of the semiconductor device shown in FIG. 30.

FIG. 32 is a left-side view of the semiconductor device shown in FIG. 30.

FIG. 33 is a sectional view taken along line XXXIII-XXXIII in FIG. 30.

FIG. 34 is a sectional view taken along line XXXIV-XXXIV in FIG. 30.

FIG. 35 is an enlarged view showing a portion of FIG. 33.

FIG. 36 is a sectional view for illustrating a step of manufacturing the semiconductor device shown in FIG. 30.

FIG. 37 is a sectional view for illustrating a step of manufacturing the semiconductor device shown in FIG. 30.

FIG. 38 is a plan view of a semiconductor device according to a third embodiment of the present disclosure, with a third resin layer shown as transparent.

FIG. 39 is a plan view corresponding to FIG. 38, with a second resin layer and a plurality of second wiring layers also shown as transparent.

FIG. 40 is a front view of the semiconductor device shown in FIG. 38.

FIG. 41 is a sectional view taken along line XLI-XLI in FIG. 39.

FIG. 42 is a plan view of a semiconductor device according to a fourth embodiment of the present disclosure, with a third resin layer shown as transparent.

FIG. 43 is a sectional view taken along line XLIII-XLIII in FIG. 42.

FIG. 44 is a sectional view taken along line XLIV-XLIV in FIG. 42.

FIG. 45 is a sectional view for illustrating a step of manufacturing the semiconductor device shown in FIG. 42.

FIG. 46 is a sectional view for illustrating a step of manufacturing the semiconductor device shown in FIG. 42.

### DETAILED DESCRIPTION OF EMBODIMENTS

Hereinafter, embodiments of the present disclosure will be described with reference to the accompanying drawings.

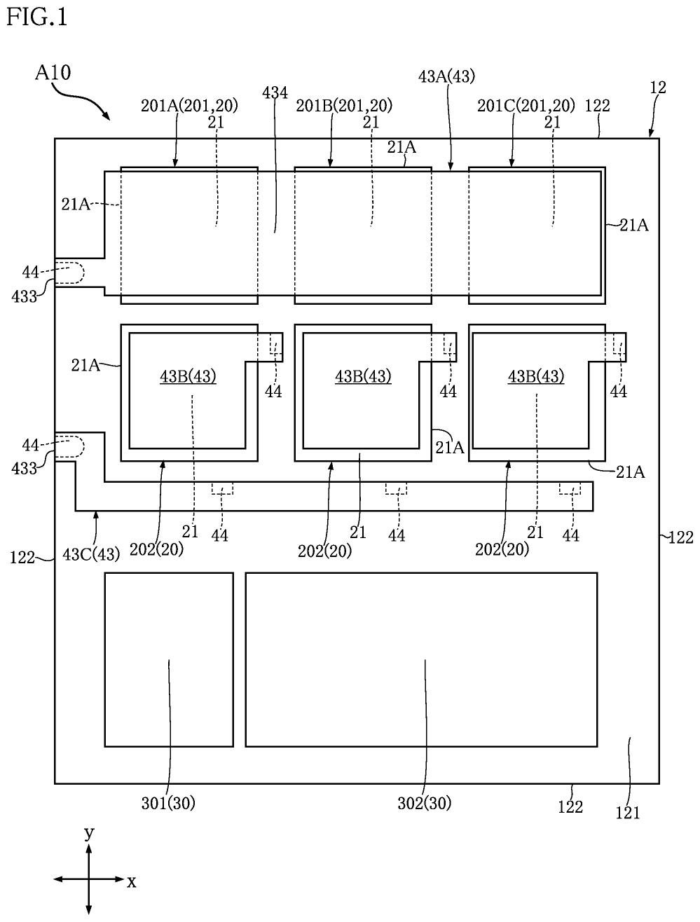

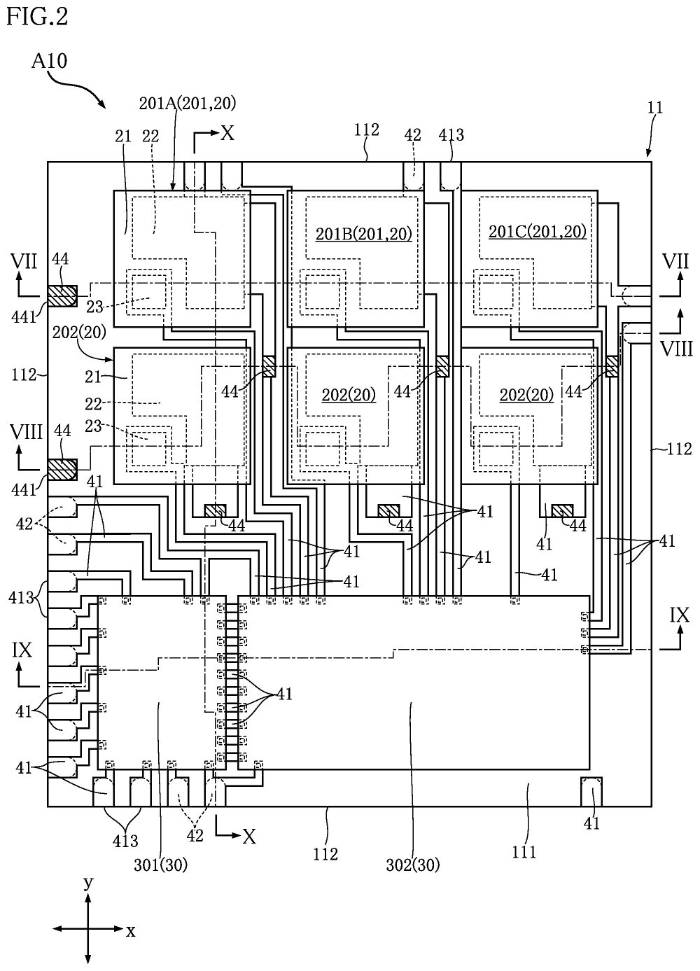

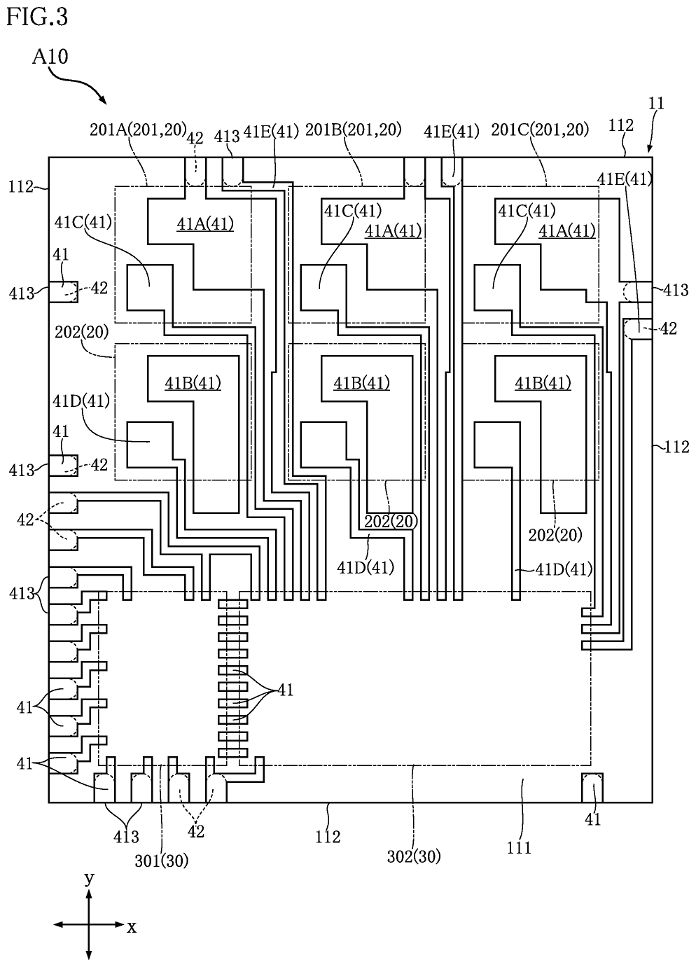

With reference to FIGS. 1 to 13, the following describes a semiconductor device A10 according to a first embodiment of the present disclosure. The semiconductor device A10 includes a first resin layer 11, a second resin layer 12, a third resin layer 13, a plurality of semiconductor elements 20, an IC 30, a plurality of first wiring layers 41, a plurality of first pillar wiring layers 42, a plurality of second wiring layers 43, a plurality of second pillar wiring layers 44, and a plurality of terminals 50. The semiconductor device A10 has a resin package for surface mounting on a wiring board. For the convenience of description, FIG. 1 shows the third resin layer 13 as transparent. FIG. 2 corresponds to FIG. 1, with the second resin layer 12 and the second wiring layers 43 also shown as transparent. Similarly, FIG. 3 corresponds to FIG. 2, with the semiconductor elements 20, the IC 30, and the second pillar wiring layers 44 also shown as transparent. In FIG. 3, the semiconductor elements 20 and the IC 30 are indicated by an imaginary line (two-dot-dash line).

For convenience of the description of the semiconductor device A10, the thickness direction of the first resin layer 11 is referred to as a “thickness direction z”. A direction orthogonal to the thickness direction z is referred to as a “first direction x”. The direction orthogonal to both the thickness direction z and the first direction x is referred to as a “second direction y”. As shown in FIG. 1. the semiconductor device A10 is rectangular as viewed in the thickness direction z.

The semiconductor device A10 converts a direct-current power supplied from an external source into a three-phase alternating-current power by the semiconductor elements 20. The semiconductor device A10 can be used for driving a brushless DC motor.

The first resin layer 11, the second resin layer 12, and the third resin layer 13 are electrically insulating. The first resin layer 11, the second resin layer 12, and the third resin layer 13 are made of a material containing a resin. In example, the resin is a black epoxy resin.

As shown in FIGS. 3, 4, and 9, the first resin layer 11 has a first obverse surface 111, a first lateral surface 112, and a bottom surface 113. The first obverse surface 111 faces in the thickness direction z. The bottom surface 113 faces away from the first obverse surface 111 in the thickness direction z. The first lateral surface 112 faces in a direction orthogonal to the thickness direction z and is connected to the first obverse surface 111 and the bottom surface 113. The first lateral surface 112 includes a pair of regions spaced apart from each other in the first direction x, and a pair of regions spaced apart from each other in the second direction y.

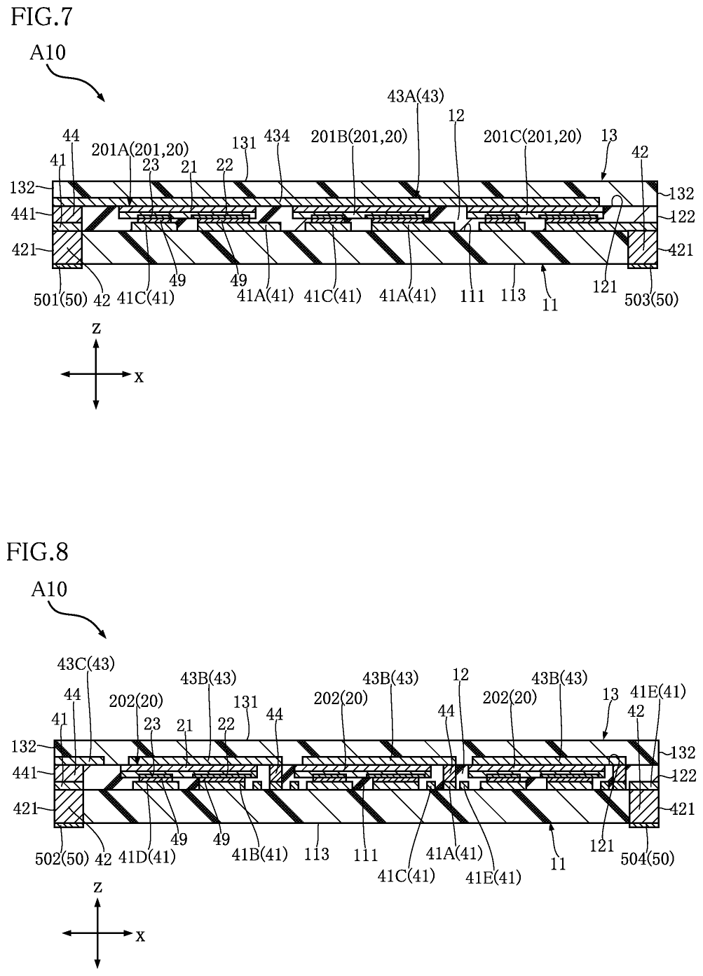

As shown in FIGS. 7 to 10, the second resin layer 12 is stacked on the first obverse surface 111 of the first resin layer 11. The second resin layer 12 is in contact with the first obverse surface 111. As shown in FIGS. 1, 9, and 10, the second resin layer 12 has a second obverse surface 121 and a second lateral surface 122. The second obverse surface 121 faces the same side as the first obverse surface 111 in the thickness direction z. The second lateral surface 122 faces in a direction orthogonal to the thickness direction z and is connected to the second obverse surface 121. The second lateral surface 122 includes a pair of regions spaced apart from each other in the first direction x, and a pair of regions spaced apart from each other in the second direction y. The second lateral surface 122 is flush with the first lateral surface 112 of the first resin layer 11.

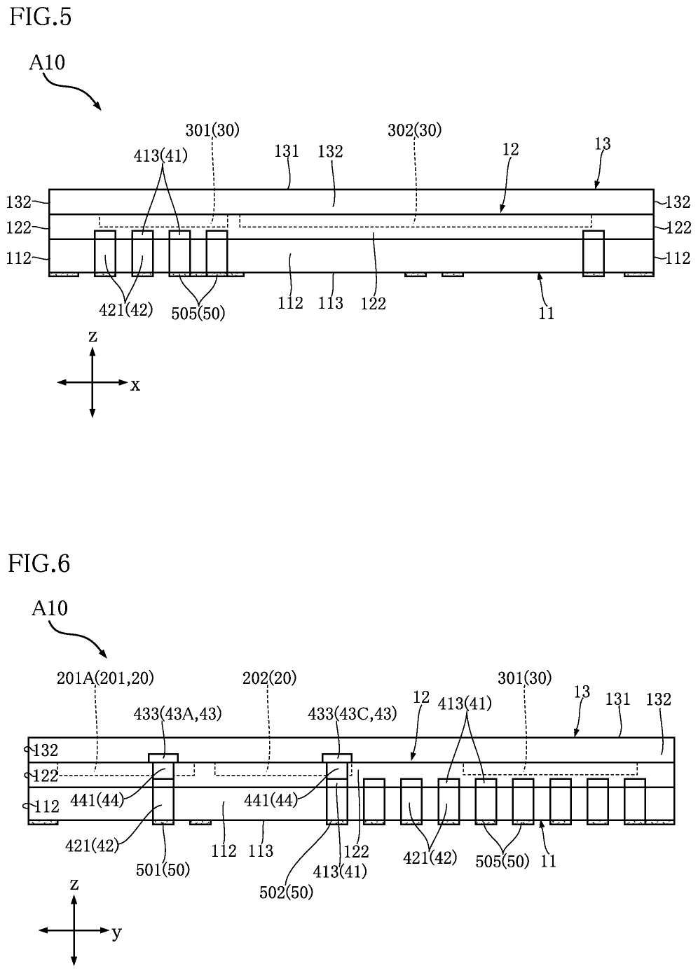

As shown in FIGS. 7 to 10, the third resin layer 13 is stacked on the second obverse surface 121 of the second resin layer 12. The third resin layer 13 is in contact with the second obverse surface 121. The third resin layer 13 is located on the side opposite the first resin layer 11 in the thickness direction z with the second resin layer 12 interposed therebetween. As shown in FIGS. 5 to 10, the third resin layer 13 has a third obverse surface 131 and a third lateral surface 132. The third obverse surface 131 faces the same side as the first obverse surface 111 of the first resin layer 11 in the thickness direction z. The third lateral surface 132 faces in a direction orthogonal to the thickness direction z and is connected to the third obverse surface 131. The third lateral surface 132 includes a pair of regions spaced apart from each other in the first direction x, and a pair of regions spaced apart from each other in the second direction y. The third lateral surface 132 is flush with the second lateral surface 122 of the second resin layer 12.

As shown in FIGS. 2, 7, and 8, the semiconductor elements 20 face the first obverse surface 111 of the first resin layer 11. The semiconductor elements 20 are covered with the second resin layer 12. The semiconductor elements 20 are vertical metal-oxide-semiconductor field-effect transistors (MOSFETs) made mainly of silicon (Si) or silicon carbide (SiC). The semiconductor elements 20 may be a different type of vertical transistors, such as insulated gate bipolar transistors (IGBTs). Here, a description is given of the semiconductor device A10 having n-channel MOSFETs as the semiconductor elements 20. As shown in FIGS. 2, 7, and 8, each semiconductor element 20 includes a semiconductor layer 21, a first electrode 22, and a second electrode 23.

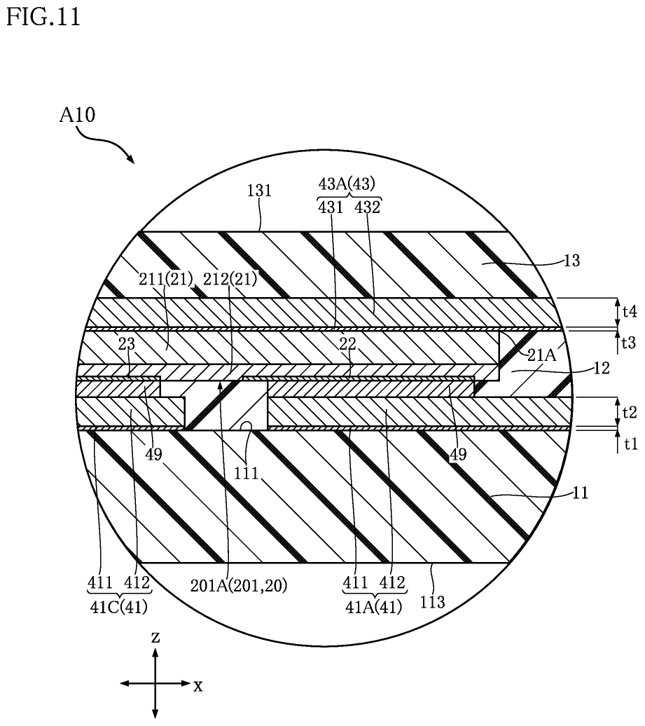

As shown in FIG. 11, the semiconductor layer 21 forms the body of the semiconductor element 20. The semiconductor layer 21 includes a first layer 211 and a second layer 212. The first layer 211 is located on the side opposite the first and second electrodes 22 and 23 in the thickness direction z with the second layer 212 interposed therebetween. The first layer 211 and the second layer 212 are electrically connected to each other. The first layer 211 is a semiconductor substrate containing an n-type semiconductor. The composition of the semiconductor substrate contains silicon. That is, the semiconductor substrate contains silicon. The current corresponding to the power to be converted by the semiconductor element 20 flows through the first layer 211. The semiconductor element 20 does not have a metal layer acting as the drain on the reverse surface. The first layer 211 serves as the drain of the semiconductor element 20. The first layer 211 is exposed from the second obverse surface 121 of the second resin layer 12. The first layer 211 is flush with the second obverse surface 121.

As shown in FIG. 11, the second layer 212 is stacked on the first layer 211. The second layer 212 may be epitaxially grown on the first layer 211. The second layer 212 contains an n-type semiconductor and a p-type semiconductor. The n-type semiconductor contained in a region of the second layer 212 in contact with the first layer 211 has a lower concentration of dopant than the n-type semiconductor contained in the first layer 211.

As shown in FIG. 11, the first electrode 22 faces the first obverse surface 111 of the first resin layer 11. The first electrode 22 is electrically connected to the second layer 212 of the semiconductor layer 21. The current corresponding to the power converted by the semiconductor element 20 flows through the first electrode 22. That is, the first electrode 22 acts the source of the semiconductor element 20.

As shown in FIG. 11, the second electrode 23 faces the first obverse surface 111 of the first resin layer 11. The second electrode 23 receives a gate voltage applied for driving the semiconductor element 20. As shown in FIG. 2, the second electrode 23 is smaller in area than the first electrode 22 as viewed in the thickness direction z.

As shown in FIG. 2, the semiconductor elements 20 include three semiconductor elements 20 belonging to a high-voltage element group 201 (hereinafter referred to as the “group of high-voltage elements 201”) and three semiconductor elements 20 belonging to a low-voltage element group 202 (hereinafter referred to as the “group of low-voltage elements 202”). In each of the group of high-voltage elements 201 and the group of low-voltage elements 202, the semiconductor elements 20 are spaced apart from each other in the first direction x. The group of low-voltage elements 202 is located between the group of high-voltage elements 201 and the IC 30 in the second direction y. The group of high-voltage elements 201 are the main components forming the upper arm circuit of the semiconductor device A10. The group of low-voltage elements 202 are the main components forming the lower arm circuit of the semiconductor device A10. That is, the gate voltage applied to each second electrode 23 is higher for the group of high-voltage elements 201 than for the group of low-voltage elements 202. In the description given below of the semiconductor device A10, the three individual semiconductor elements 20 belonging to the group of high-voltage elements 201 are referred to as a first element 201A, a second element 201B, and a third element 201C for convenience.

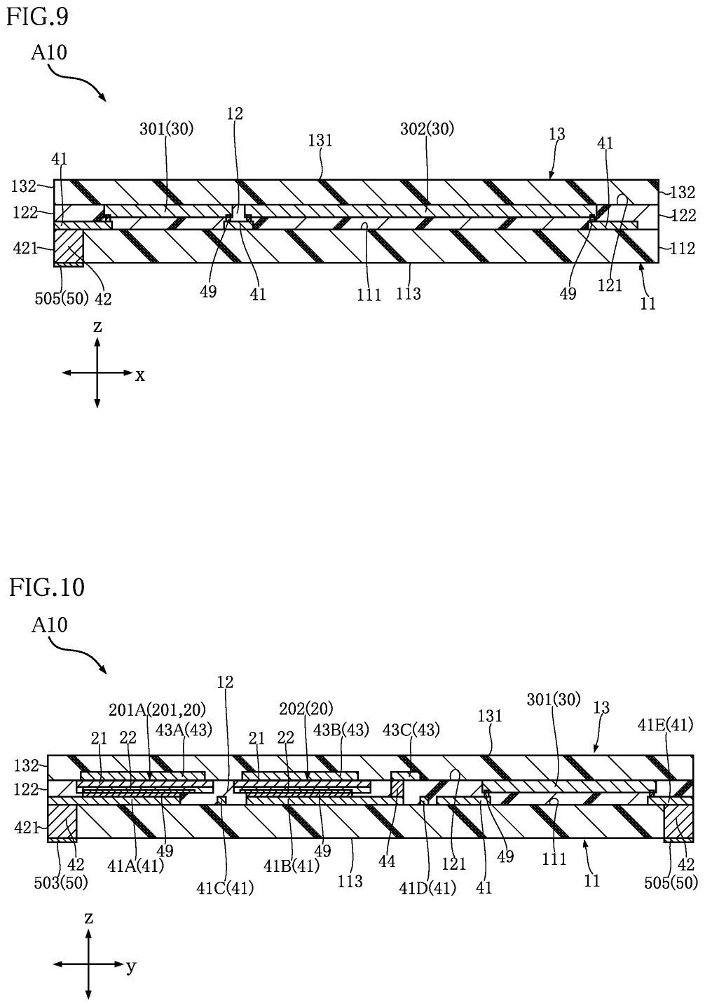

As shown in FIGS. 2 and 9, the IC 30 faces the first obverse surface 111 of the first resin layer 11. The IC 30 is covered with the second resin layer 12. In the semiconductor device A10, the IC 30 includes a first IC 301 and a second IC 302 spaced apart from each other in the first direction x. The first IC 301 and the second IC 302 are electrically connected to each other via a plurality of first wiring layers 41. The first IC 301 is a controller for controlling the second IC 302. The second IC 302 is a gate driver for applying a gate voltage to each second electrode 23 of the group of high-voltage elements 201 and the group of low-voltage elements 202. In a different example, the IC 30 may be constructed as a single structure including a controller and a gate driver. As shown in FIG. 1, the semiconductor device A10 has the upper surfaces of the first IC 301 and the second IC 302 exposed from the second obverse surface 121 of the second resin layer 12. The respective upper surfaces are flush with the second obverse surface 121. In an alternative structure, the first IC 301 and the second IC 302 may not be exposed from the second resin layer 12.

As shown in FIGS. 3 and 7 to 10, the first wiring layers 41 face the first obverse surface 111 of the first resin layer 11. The first wiring layers 41 are in contact with the first obverse surface 111. At least a portion of the first wiring layers 41 is covered with the second resin layer 12. The first wiring layers 41, together with the first pillar wiring layers 42, the second wiring layers 43, and the second pillar wiring layers 44, form conductive paths that connect the semiconductor elements 20 and the IC 30 to a wiring board when the semiconductor device A10 is mounted thereon.

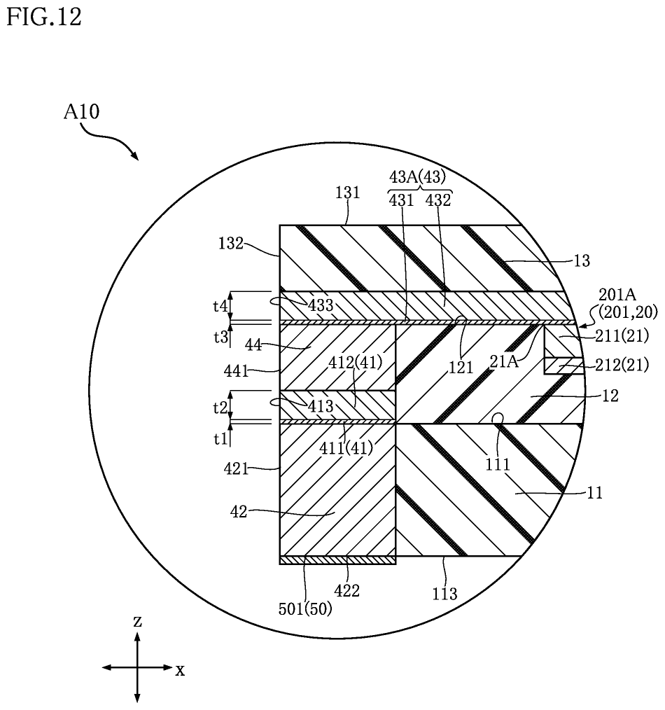

As shown in FIGS. 11 and 12, each first wiring layer 41 includes a first conductive layer 411 in contact with the first obverse surface 111 of the first resin layer 11, and a second conductive layer 412 stacked on the first conductive layer 411. The first conductive layer 411 includes a barrier layer in contact with the first obverse surface 111, and a seed layer stacked on the barrier layer. The barrier layer contains nickel (Ni). In a different example, the barrier layer may contain titanium (Ti). The seed layer contains copper (Cu), for example. The second conductive layer 412 contains copper, for example. The second conductive layer 412 has a thickness t2, and the first conductive layer 411 has a thickness t1, where the thickness t2 is greater than the thickness t1.

As shown in FIG. 3, the first wiring layers 41 include a plurality of first output wiring parts 41A, a plurality of second output wiring parts 41B, a plurality of first gate wiring parts 41C, a plurality of second gate wiring parts 41D, and a plurality of boot wiring parts 41E.

As shown in FIG. 7, the first electrodes 22 of the group of high-voltage elements 201 are electrically bonded to the first output wiring parts 41A via a conductive bonding layer 49. The conductive bonding layer 49 includes a nickel layer stacked on the second conductive layer 412 of a relevant first wiring layer 41, and an alloy layer stacked on the nickel layer. The alloy layer contains tin (Sn). The second IC 302 includes a plurality of electrodes (not shown) each of which is electrically bonded to a first output wiring part 41A via the conductive bonding layer 49. With this arrangement, the voltage applied to the first output wiring parts 41A is set as the ground for the gate voltage applied to the second electrodes 23 of the group of high-voltage elements 201.

As shown in FIG. 8, the first electrodes 22 of the group of low-voltage elements 202 are electrically bonded to the second output wiring parts 41B via the conductive bonding layer 49. The second output wiring parts 41B are not exposed from the second resin layer 12.

As shown in FIG. 7, the second electrodes 23 of the group of high-voltage elements 201 are electrically bonded to the first gate wiring parts 41C via the conductive bonding layer 49. The second IC 302 also includes a plurality of electrodes each of which is electrically bonded to a first gate wiring part 41C via the conductive bonding layer 49. When the second IC 302 applies a gate voltage to a second electrode 23 of the group of high-voltage elements 201, the current flows from the second IC 302 to that second electrode 23 via a relevant first gate wiring part 41C. The first gate wiring parts 41C are not exposed from the second resin layer 12.

As shown in FIG. 8, the second electrodes 23 of the group of low-voltage elements 202 are electrically bonded to the second gate wiring parts 41D via the conductive bonding layer 49. The second IC 302 also includes a plurality of electrodes each of which is electrically bonded to a second gate wiring part 41D via the conductive bonding layer 49. When the second IC 302 applies a gate voltage to a second electrode 23 of the group of low-voltage elements 202, the current flows from the second IC 302 to that second electrode 23 via a relevant second gate wiring part 41D. The second gate wiring parts 41D are not exposed from the second resin layer 12.

As shown in FIG. 10, the second IC 302 also includes a plurality of electrodes each of which is electrically bonded to a boot wiring part 41E via the conductive bonding layer 49. The gate voltage applied to each second electrode 23 of the group of high-voltage elements 201 is increased by a bootstrap circuit to a voltage higher than the voltage applied to the first layer 211 of each semiconductor layer 21 of the group of high-voltage elements 201. The boot wiring parts 41E are components of the bootstrap circuit.

The first IC 301 and the second IC 302 also include a plurality of electrodes (not illustrated) electrically bonded to the individual first wiring layers 41 other than the first output wiring parts 41A, the second output wiring parts 41B, the first gate wiring parts 41C, the second gate wiring parts 41D, and the boot wiring parts 41E, via the conductive bonding layer 49.

As shown in FIGS. 2, 3, 5, and 6, in the semiconductor device A10, each first wiring layer 41 other than the second output wiring parts 41B, the first gate wiring parts 41C, and the second gate wiring parts 41D has a first end face 413. The first end face 413 faces either in the first direction x or in the second direction y and is exposed from the second lateral surface 122 of the second resin layer 12. The first end face 413 is flush with the second lateral surface 122.

As shown in FIGS. 7 to 10, the first pillar wiring layers 42 are embedded in the first resin layer 11. As shown in FIGS. 3 and 12, each first pillar wiring layer 42 is in contact with the first conductive layer 411 of a first wiring layer 41 other than the second output wiring parts 41B, the first gate wiring parts 41C, and the second gate wiring parts 41D. Hence, each first pillar wiring layer 42 is electrically connected to a relevant first wiring layer 41, which is not the second output wiring parts 41B, the first gate wiring parts 41C, and the second gate wiring parts 41D. The first pillar wiring layers 42 contain copper, for example.

As shown in FIG. 12, each first pillar wiring layer 42 has a second end face 421 and a reverse surface 422. The second end face 421 faces either in the first direction x or in the second direction y and is exposed from the first lateral surface 112 of the first resin layer 11. The second end face 421 is flush with the first lateral surface 112. The reverse surface 422 faces away from the first obverse surface 111 of the first resin layer 11 in the thickness direction z. The reverse surface 422 is exposed from the bottom surface 113 of the first resin layer 11.

As shown in FIGS. 1, 7, 8, and 10, the second wiring layers 43 face the second obverse surface 121 of the second resin layer 12. The second wiring layers 43 are in contact with the second obverse surface 121. At least a portion of the second wiring layers 43 is covered with the third resin layer 13.

As shown in FIGS. 11 and 12, each second wiring layer 43 includes a first conductive layer 431 in contact with the second obverse surface 121 of the second resin layer 12, and a second conductive layer 432 stacked on the first conductive layer 431. The first conductive layer 431 includes a barrier layer in contact with the second obverse surface 121 and a seed layer stacked on the barrier layer. The barrier layer contains nickel. In another example, the barrier layer may contain titanium. The seed layer contains copper, for example. The second conductive layer 432 contains copper, for example. The second conductive layer 432 has a thickness t4, and the first conductive layer 431 has a thickness t3, where the thickness t4 is greater than the thickness t3.

As shown in FIG. 1, the second wiring layers 43 include a first input wiring part 43A, a plurality of second input wiring parts 43B, and a ground wiring part 43C.

As shown in FIGS. 7 and 11, the first input wiring part 43A is in contact with the first layers 211 of the semiconductor layers 21 of the group of high-voltage elements 201. The first input wiring part 43A is thus electrically connected to the semiconductor layers 21 (the first layers 211) of the group of high-voltage elements 201. As shown in FIG. 1, the first input wiring part 43A extends across the outer edge 21A of each semiconductor layer 21 of the group of high-voltage elements 201 as viewed in the thickness direction z. As viewed in the thickness direction z, the first input wiring part 43A overlaps with the group of high-voltage elements 201 and also with the plurality of first output wiring parts 41A.

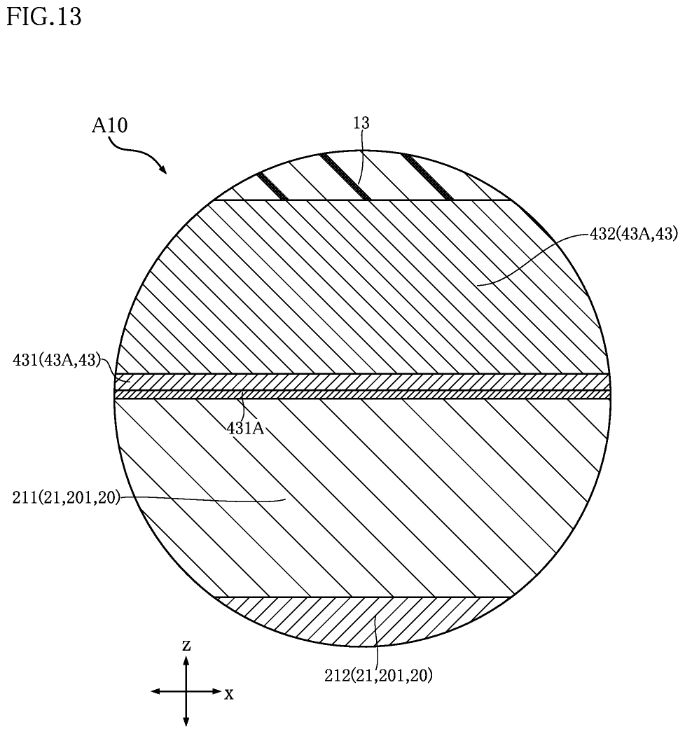

As shown in FIG. 13, the first conductive layer 431 of the first input wiring part 43A includes a silicide layer 431A. The silicide layer 431A is in contact with the first layer 211 of at least one semiconductor layer 21 of the group of high-voltage elements 201. The main component of the silicide layer 431A is a silicide of metal contained in the barrier layer of the first conductive layer 431. Hence, when the barrier layer contains nickel, a nickel silicide is the main component of the silicide layer 431A.

As shown in FIG. 1, the first input wiring part 43A includes a strip part 434 extending in the first direction x. The strip part 434 includes a portion located between the first element 201A and the second element 201B as viewed in the thickness direction z. The strip part 434 also includes a portion located between the second element 201B and the third element 201C as viewed in the thickness direction z.

As shown in FIG. 1, the second input wiring parts 43B are located between the first input wiring part 43A and the ground wiring part 43C in the second direction y. The second input wiring parts 43B are spaced apart from each other in the first direction x. The second input wiring parts 43B are in contact with the first layers 211 of the semiconductor layers 21 of the group of low-voltage elements 202. Hence, the second input wiring parts 43B are electrically connected to the relevant semiconductor layers 21 (the first layers 211) of the group of low-voltage elements 202. As shown in FIG. 1, each second input wiring part 43B extends across the outer edge 21A of a semiconductor layer 21 of the group of low-voltage elements 202. As viewed in the thickness direction z, the second input wiring parts 43B overlap with the group of low-voltage elements 202 and the second output wiring parts 41B. The second input wiring parts 43B are not exposed from the third resin layer 13.

As shown in FIG. 1, the ground wiring part 43C is located on the side opposite the first input wiring part 43A in the second direction y with the second input wiring parts 43B interposed therebetween. The ground wiring part 43C has a strip-shaped portion extending in the first direction x.

As shown in FIGS. 1 and 5, in the semiconductor device A10, the first input wiring part 43A and the ground wiring part 43C have a third end face 433. The third end face 433 faces in the first direction x and is exposed from the third lateral surface 132 of the third resin layer 13. The third end face 433 is flush with the third lateral surface 132.

As shown in FIGS. 7, 8, and 10, the second pillar wiring layers 44 are embedded in the second resin layer 12. In FIG. 2, the second pillar wiring layers 44 are hatched. As shown in FIGS. 1, 2, and 12, each second pillar wiring layer 44 is in contact with the second conductive layer 412 of a first wiring layer 41 and the first conductive layer 431 of a second wiring layer 43. This electrically connects the second input wiring parts 43B to the first output wiring parts 41A. The ground wiring part 43C is electrically connected to the second output wiring parts 41B. Additionally, each of the first input wiring part 43A and the ground wiring part 43C is electrically connected to a first wiring layer 41 other than the first output wiring parts 41A, the second output wiring parts 41B, the first gate wiring parts 41C, the second gate wiring parts 41D, and the boot wiring parts 41E. The second pillar wiring layers 44 contain copper, for example.

As shown in FIGS. 2 and 6, in the semiconductor device A10, two of the second pillar wiring layers 44 are in contact with the first input wiring part 43A or the ground wiring part 43C, and these two second pillar wiring layers 44 each have a fourth end face 441. The fourth end face 441 faces in the first direction x and is exposed from the second lateral surface 122 of the second resin layer 12. The fourth end face 441 is flush with the second lateral surface 122.

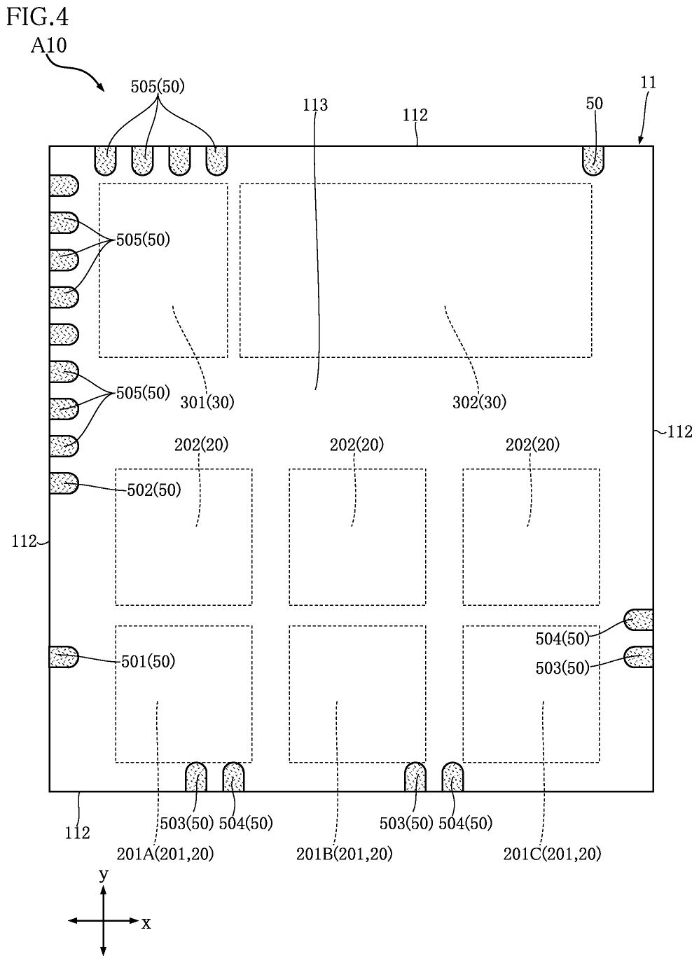

As shown in FIGS. 7 to 10, the terminals 50 are disposed in contact with the first pillar wiring layers 42. This electrically connects the terminals 50 to the first pillar wiring layers 42. The terminals 50 cover the reverse surfaces 422 of the first pillar wiring layers 42. In FIGS. 4 to 6, the terminals 50 are shown as stippled regions. The terminals 50 are exposed from the first resin layer 11. To mount the semiconductor device A10 onto a wiring board, the terminals 50 are soldered to the wiring board. Each terminal 50 includes a laminate of metal layers disposed on a first pillar wiring layer 42. The metal layers include a layer of nickel and a layer of gold (Au) deposited on the first pillar wiring layer 42 in the stated order. In a different example, the metal layers may include a layer of nickel, a layer of palladium (Pd), and a layer of gold deposited on the first pillar wiring layer 42 in the stated order.

As shown in FIG. 4, the terminals 50 include a first terminal 501, a second terminal 502, a plurality of third terminals 503, a plurality of fourth terminals 504, and a plurality of fifth terminals 505.

The first terminal 501 is electrically connected to the first input wiring part 43A. The second terminal 502 is electrically connected to the ground wiring part 43C and thus to the second output wiring parts 41B. The first terminal 501 and the second terminal 502 will receive a direct-current power to be converted by the semiconductor elements 20. The first terminal 501 is a positive electrode (P terminal). The second terminal 502 is a negative electrode (N terminal).

The third terminals 503 are electrically connected to the first output wiring parts 41A. The third terminals 503 are electrically connected also to capacitors external to the semiconductor device A10. The capacitors are components of the bootstrap circuit associated with the semiconductor device A10. The third terminals 503 output the U-phase, V-phase, and W-phase of a three-phase electric power converted by the semiconductor elements 20. The three-phase electric power is used to drive the motor external to the semiconductor device A10.

The fourth terminals 504 are electrically connected to the boot wiring parts 41E. The fourth terminals 504 are electrically connected also to capacitors external to the semiconductor device A10. When the second IC 302 applies a gate voltage to a second electrode 23 of the group of high-voltage elements 201, a current flows into the second IC 302 from a relevant capacitor via the fourth terminal 504 and the boot wiring part 41E electrically connected to that capacitor.

The fifth terminals 505 are electrically connected to the IC 30. One of the fifth terminals 505 is used to input electric power for driving the IC 30. One of the fifth terminals 505 is used to input an electric signal to the first IC 301. One of the fifth terminals 505 is used to output an electric signal from the first IC 301.

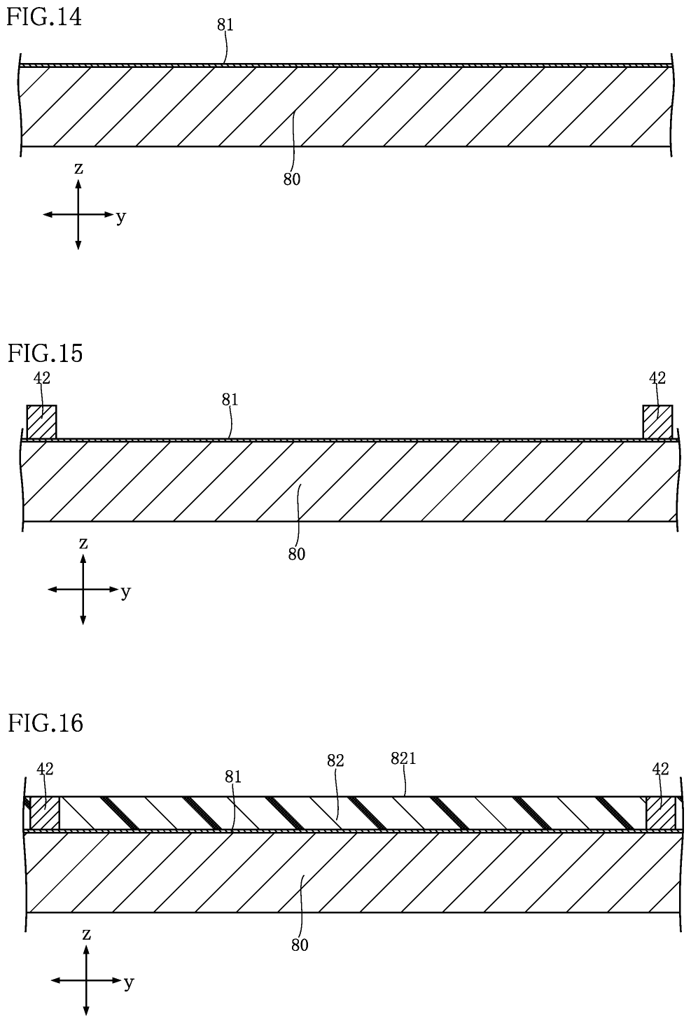

Next, an example of a method of manufacturing the semiconductor device A10 will be described with reference to FIGS. 14 to 29. Note that the sections shown in FIGS. 14 to 29 are taken along the same line as the section shown in in FIG. 10.

As shown in FIG. 14, the method of manufacturing begins with forming a release layer 81 that covers one surface of a base 80 in the thickness direction z (the upper surface in the figure). The base 80 is a semiconductor wafer (silicon wafer). The base 80 has an insulating film (not shown) formed on its surface. The insulating film is an oxide film (SiO₂) or a nitride film (Si₃N₄). The oxide film can be formed by thermal oxidation. The nitride film can be formed by plasma chemical vapor deposition (CVD). Strictly speaking, the release layer 81 is in contact with the insulating film formed on the base 80. The release layer 81 is composed of thin films of metals, one of which is a titanium film and another is a copper film stacked on the titanium film. The release layer 81 is formed by depositing these thin films of metals by sputtering.

Subsequently, as shown in FIG. 15, the method proceeds to forming a plurality of first pillar wiring layers 42 protruding from the release layer 81 in the thickness direction z. The first pillar wiring layers 42 are formed by lithography patterning of the release layer 81 and subsequent electroplating using the release layer 81 as a conductive path.

Subsequently, as shown in FIG. 16, the method proceeds to forming a first resin layer 82 that has a first obverse surface 821 facing in the thickness direction z and that covers a portion of a first pillar wiring layer 42. The first resin layer 82 corresponds to the first resin layer 11 in the semiconductor device A10. The first resin layer 82 is made of a material containing a black epoxy resin with filler. The first resin layer 82 is formed by compression molding. The first resin layer 82 as formed by compression molding is in contact with the release layer 81 and initially covers all portions the first pillar wiring layers 42. Then, portions of the first resin layer 82 and portions of the first pillar wiring layers 42 are removed by grinding. Note that grinding is applied to the side away from the base 80 in the thickness direction z. In this way, the first resin layer 82 is formed with the first obverse surface 821 facing in the thickness direction z. The first obverse surface 821 corresponds to the first obverse surface 111 of the first resin layer 11 in the semiconductor device A10. The upper surfaces of the first pillar wiring layers 42 are exposed from the first obverse surface 821.

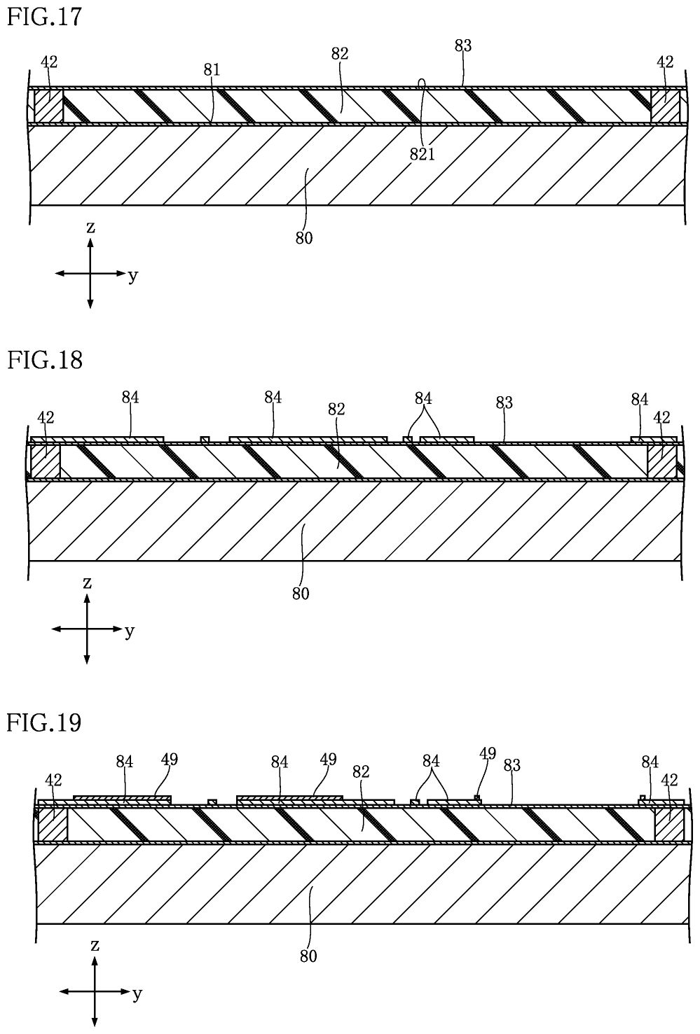

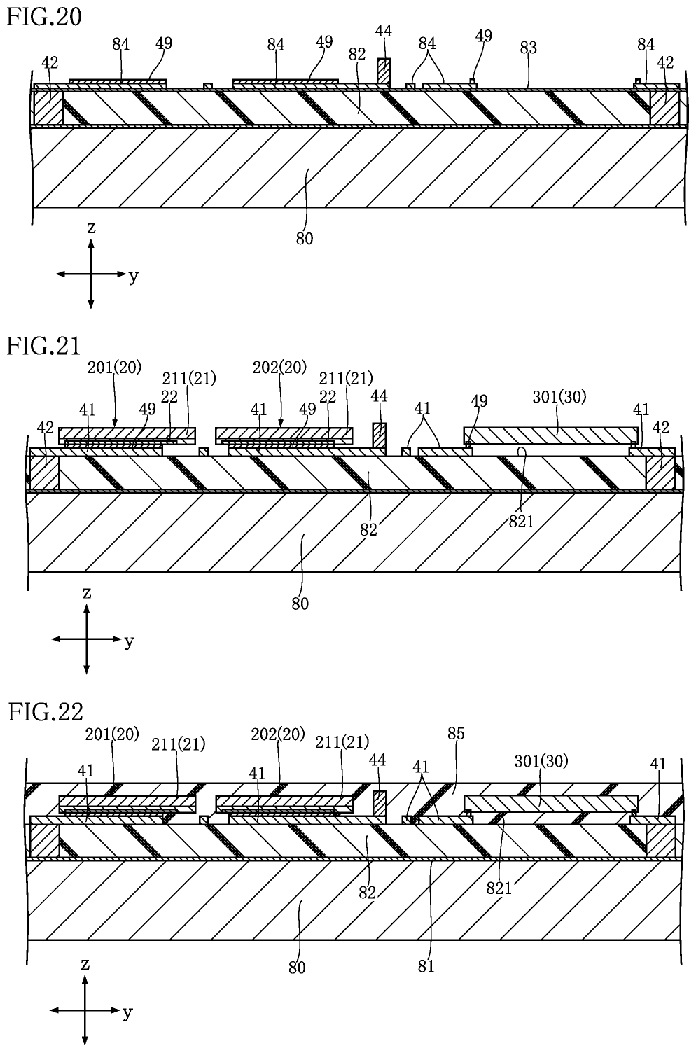

Subsequently, the method proceeds to forming a plurality of first wiring layers 41 (see FIG. 21) facing the first obverse surface 821 of the first resin layer 82, a conductive bonding layer 49 shown in FIG. 19, and a plurality of second pillar wiring layers 44 shown in FIG. 20.

As shown in FIG. 17, this begins with forming a first underlying layer 83 that covers the first obverse surface 821 of the first resin layer 82 and the upper surfaces of the first pillar wiring layers 42. The first underlying layer 83 corresponds to the first conductive layers 411 of the first wiring layers 41. The first underlying layer 83 is formed by depositing a barrier layer on the relevant surfaces by sputtering and then depositing a seed layer on the barrier layer by sputtering. The barrier layer is made of nickel with a thickness of at least 100 nm and at most 300 nm. In another example, the barrier layer may be made of titanium. The seed layer is made of copper with a thickness of at least 200 nm and at most 600 nm.

Then, as shown in FIG. 18, the method proceeds to forming a plurality of first plating layers 84 in contact with the first underlying layer 83. The first plating layers 84 correspond to the second conductive layers 412 of the first wiring layers 41. The first plating layers 84 are made of copper. The first plating layers 84 are formed by lithography patterning of the first underlying layer 83, and subsequent electroplating using the first underlying layer 83 as a conductive path.

Subsequently, as shown in FIG. 19, the method proceeds to forming a conductive bonding layer 49 protruding from a first plating layer 84 in the thickness direction z. The conductive bonding layer 49 is formed by lithography patterning of the first underlying layer 83 and the first plating layers 84, and subsequent electroplating using the first underlying layer 83 and the first plating layers 84 as conductive paths.

Subsequently, as shown in FIG. 20, the method proceeds to forming a plurality of second pillar wiring layers 44 each protruding from a first plating layer 84 in the thickness direction z. The second pillar wiring layers 44 are formed by lithography patterning of the first underlying layer 83, the first plating layers 84, and the conductive bonding layer 49, and subsequent electroplating using the first underlying layer 83 and the first plating layers 84 as conductive paths. Then, the portions of the first underlying layer 83 not covered by the first plating layers 84 are removed. The portions of the first underlying layer 83 are removed by wet etching using a mixture solution of sulfuric acid (H₂SO₄) and hydrogen peroxide (H₂O₂). In this way, the first wiring layers 41 shown in FIG. 21 are formed.

Subsequently, as shown in FIG. 21, the method proceeds to electrically bonding the first wiring layers 41 to a plurality of semiconductor elements 20 and an IC 30. This begins with temporary attaching, with the use of a flip chip bonder, the first electrode 22 and the second electrode 23 of each semiconductor element 20 and the electrodes (not shown) of the IC 30 to the conductive bonding layer 49. Then, the reflow process is performed to melt the conductive bonding layer 49, followed by cooling the melted conductive bonding layer 49 to solidify. In this way, the first electrodes 22 and the second electrodes 23 of the semiconductor elements, 20 are electrically bonded to the first wiring layers 41. In addition, the electrodes of the IC 30 are electrically bonded to the first wiring layers 41.

Subsequently, as shown in FIGS. 22 to 24, the method proceeds to forming a second resin layer 85 that has a second obverse surface 851 facing the same direction as the first obverse surface 821 of the first resin layer 82 in the thickness direction z and that covers a portion of each semiconductor element 20 and a portion of the IC 30. The second resin layer 85 corresponds to the second resin layer 12 of the semiconductor device A10.

As shown in FIG. 22, this begins with forming a second resin layer 85 to cover all portions of the semiconductor elements 20, the IC 30, the first wiring layers 41, and the second pillar wiring layers 44. The second resin layer 85 is made of a material containing a black epoxy resin with filler. The second resin layer 85 is formed by compression molding. The second resin layer 85 as formed by compression molding is in contact with the first obverse surface 821 of the first resin layer 82 and initially covers all portions the semiconductor elements 20, the IC 30, the first wiring layers 41, and the second pillar wiring layers 44.

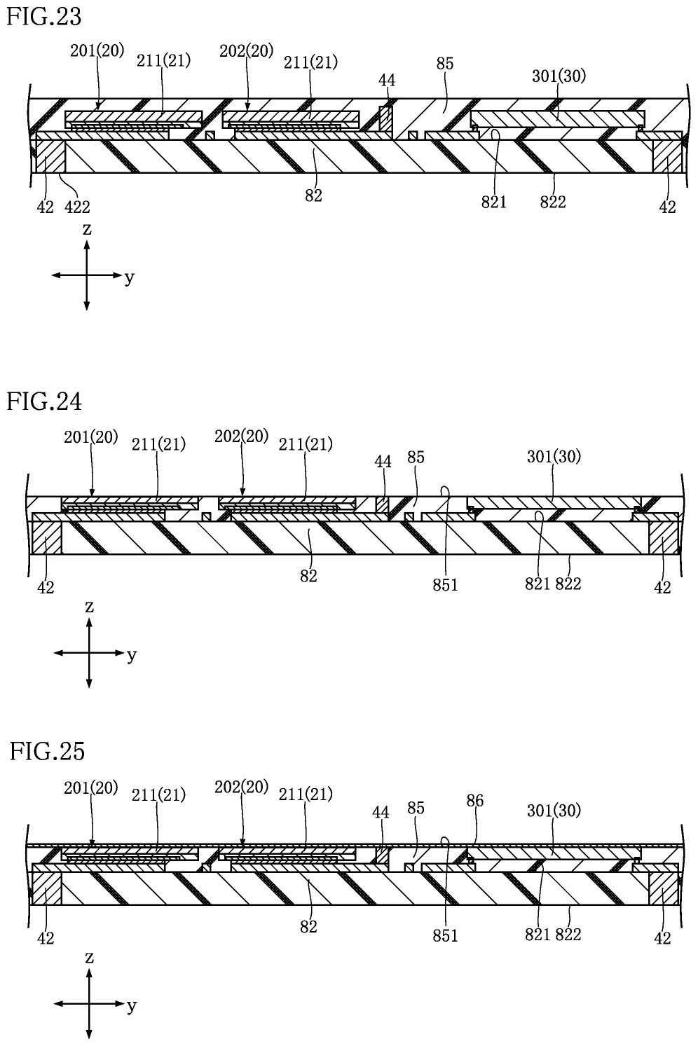

Subsequently, as shown in FIG. 23, the method proceeds to removing the base 80 and the release layer 81. The base 80 is removed by grinding. The release layer 81 is removed by wet etching using a mixture solution of sulfuric acid and hydrogen peroxide. In this way, the first resin layer 82 is formed with a bottom surface 822 facing away from the first obverse surface 821 in the thickness direction z. The bottom surface 822 corresponds to the bottom surface 113 of the first resin layer 11 in the semiconductor device A10. The reverse surfaces 422 of the first pillar wiring layer 42 are exposed from the bottom surface 822.

Subsequently, as shown in FIG. 24, the method proceeds to removing a portion of the second resin layer 85 and a portion of each semiconductor element 20, and a portion of the IC 30 by grinding. Note that grinding is applied to the side away from the first resin layer 82 in the thickness direction z. In this way, the second resin layer 85 is formed with the second obverse surface 851. The second obverse surface 851 corresponds to the second obverse surface 121 of the second resin layer 12 in the semiconductor device A10. The second obverse surface 851 has the semiconductor layers 21 (the first layers 211) of the semiconductor elements 20, the upper surface of the IC 30, and the upper surfaces of the second pillar wiring layers 44 exposed therefrom.

Subsequently, the method proceeds to forming a plurality of second wiring layers 43 (see FIG. 27) facing the second obverse surface 851 of the second resin layer 85 and electrically connected to the semiconductor elements 20.

As shown in FIG. 25, this begins with forming a second underlying layer 86 to cover the second obverse surface 851 of the second resin layer 85, the semiconductor layers 21 (the first layers 211) of the semiconductor elements 20, the upper surface of the IC 30, and the upper surfaces of the second pillar wiring layers 44. The second underlying layer 86 corresponds to the first conductive layers 431 of the second wiring layers 43. The second underlying layer 86 is formed by depositing a barrier layer on the relevant surfaces by sputtering and then depositing a seed layer on the barrier layer by sputtering. The barrier layer is made of nickel with a thickness of at least 100 nm and at most 300 nm. In another example, the barrier layer may be made of titanium. The seed layer is made of copper with a thickness of at least 200 nm and at most 600 nm.

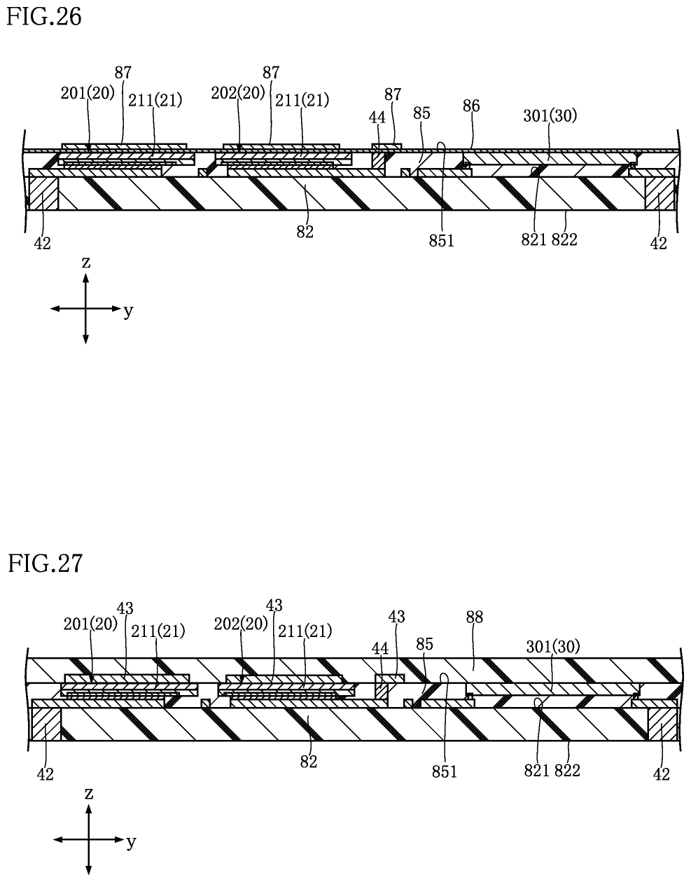

Subsequently, as shown in FIG. 26, the method proceeds to forming a plurality of second plating layers 87 in contact with the underlying layer 86. The second plating layers 87 correspond to the second conductive layers 432 of the second wiring layers 43. The second plating layers 87 are made of copper. The second plating layers 87 are formed by lithography patterning of the second underlying layer 86 and subsequent electroplating using the second underlying layer 86 as a conductive path. Of the plurality of second plating layers 87, each second plating layer 87 that overlaps with the semiconductor layer 21 of a semiconductor element 20 is formed to extend across the outer edge 21A of the semiconductor layer 21 as viewed in the thickness direction z (see FIGS. 1 and 11).

Subsequently, the method proceeds to removing the portions of the second underlying layer 86 not covered by the second plating layers 87. The portions of the second underlying layer 86 are removed by wet etching using a mixture solution of sulfuric acid and hydrogen peroxide. In this way, the second wiring layers 43 shown in FIG. 27 are formed. Of the second wiring layers 43, each second wiring layer 43 overlapping with the semiconductor layer 21 of a semiconductor element 20 extends across the outer edge 21A of the semiconductor layer 21 as viewed in the thickness direction z and in contact with the semiconductor layer 21 (see FIG. 11).

Subsequently, as shown in FIG. 27, the method proceeds to forming a third resin layer 88 that faces the second obverse surface 851 of the second resin layer 85 and that covers the second wiring layers 43. The third resin layer 88 corresponds to the third resin layer 13 of the semiconductor device A10. The third resin layer 88 is made of a material containing a black epoxy resin with filler. The third resin layer 88 is formed by compression molding. The third resin layer 88 as formed by compression molding is in contact with the second obverse surface 851 of the second resin layer 85.

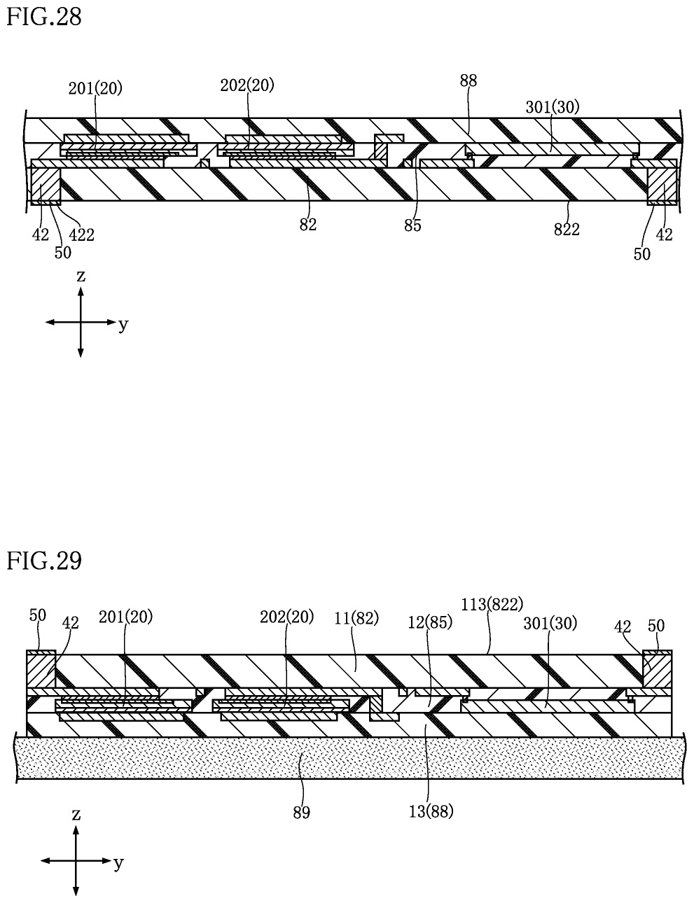

Subsequently, as shown in FIG. 28, the method proceeds to forming a plurality of terminals 50 covering the reverse surfaces 422 of the first pillar wiring layers 42 exposed from the bottom surface 822 of the first resin layer 82. The terminals 50 are formed by electroless plating.

Finally, the method proceeds to separating individual dies. This includes attaching a tape 89 to the surface of the third resin layer 88 facing in the thickness direction z, and cutting the first resin layer 82, the second resin layer 85, and the third resin layer 88 along the grid lines parallel to the first direction x and the second direction y. For the process of cutting, a dicing blade may be used. In this way, the first resin layer 82, the second resin layer 85 and the third resin layer 88 of each separated die serve as the first resin layer 11, the second resin layer 12, and the third resin layer 13 of a semiconductor device A10. Through the above processing steps, the semiconductor device A10 is obtained.

Next, the operation and effect of the semiconductor device A10 will be described.

The semiconductor device A10 includes: a first wiring layer 41 facing a first obverse surface 111 of a first resin layer 11; a semiconductor element 20 having a semiconductor layer 21 and an electrode (a first electrode 22); a second resin layer 12 covering a portion of the semiconductor element 20; and a second wiring layer 43 facing a second obverse surface 121 of the second resin layer 12. The electrode of the semiconductor element 20 is electrically bonded to the first wiring layer 41. The second wiring layer 43 is in contact with the semiconductor layer 21 and electrically connected to the semiconductor layer 21. The second wiring layer 43 extends across the outer edge 21A of the semiconductor layer 21 as viewed in the thickness direction z. With this configuration, the semiconductor element 20 overlaps with the first wiring layer 41 and the second wiring layer 43 as viewed in the thickness direction z. This allows the semiconductor device A10 to be compact. In addition, the second wiring layer 43 is electrically connected to the semiconductor layer 21, without a bonding layer made of e.g., solder, nor a reverse surface metal layer, which may be commonly disposed on the semiconductor element 20. The first wiring layer 41 is electrically connected to the electrode of the semiconductor element 20 via a conductive bonding layer 49 shown in FIG. 11 and not via a wire. This configuration serves to reduce the parasitic resistance of the semiconductor device A10. The present embodiment can therefore reduce the size and the parasitic resistance of the semiconductor device A10.

The semiconductor layer 21 of the semiconductor element 20 includes a first layer 211 and a second layer 212. The second wiring layer 43 is in contact with the first layer 211. Thus, when portions of the semiconductor element 20 and the second resin layer 85 are removed in the manufacturing process of the semiconductor device A10 as shown in FIG. 24, the first layer 211 corresponding to a semiconductor substrate is partly removed but the epitaxially grown second layer 212 is not removed. With the method for forming the semiconductor device A10, the second wiring layer 43 that is in contact with the first layer 211 can be formed without affecting the functionality of the semiconductor element 20.

The first layer 211 of the semiconductor layer 21 is flush with the second obverse surface 121 of the second resin layer 12. This allows the second wiring layer 43 to have a uniform sectional shape in a direction orthogonal to the thickness direction z. This serves to reduce the parasitic resistance of the semiconductor device A10.

The second wiring layer 43 includes a first conductive layer 431 and a second conductive layer 432. The first conductive layer 431 includes a silicide layer 431A in contact with the first layer 211 of the semiconductor layer 21. Thus, the second wiring layer 43 forms an ohmic contact with the first layer 211. This configuration serves to reduce the formation of a depletion layer in the first layer 211 during operation of the semiconductor device A10. In addition, when nickel is contained in the first conductive layer 431, the silicide layer 431A can be formed at relatively low temperatures.

The semiconductor device A10 further includes a first pillar wiring layer 42 embedded in the first resin layer 11. The first pillar wiring layer 42 is in contact with the first wiring layer 41. In this way, although the first wiring layer 41 is entirely covered with the first resin layer 11 and the second resin layer 12, a conductive path is provided from the first wiring layer 41 to a wiring board when the semiconductor device A10 is mounted on the wiring board. This configuration does not require increasing the size of the semiconductor device A10.

The semiconductor device A10 further includes a second pillar wiring layer 44 embedded in the second resin layer 12. The second pillar wiring layer 44 is in contact with the first wiring layer 41 and the second wiring layer 43. With this configuration, a conductive path is provided between the first wiring layer 41 and the second wiring layer 43 without a need to increase the size of the semiconductor device A10.

The semiconductor device A10 further includes a terminal 50 in contact with the first pillar wiring layer 42. The terminal 50 is exposed from the first resin layer 11. This improvise solder wettability, because solder applied for attaching the semiconductor device A10 to a wiring board will adhere to the terminal 50.

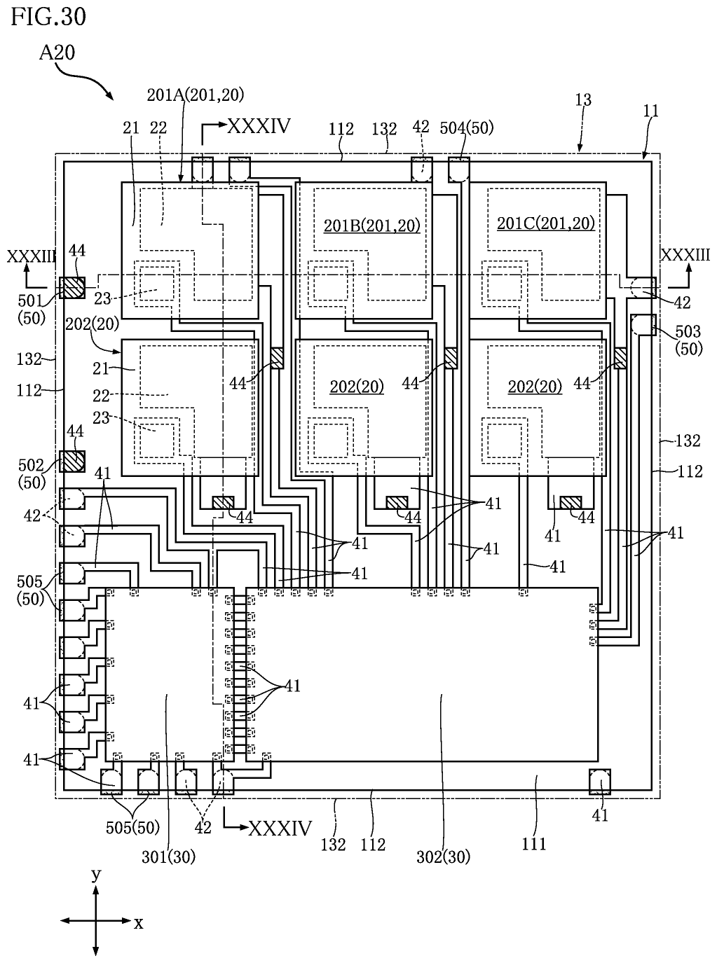

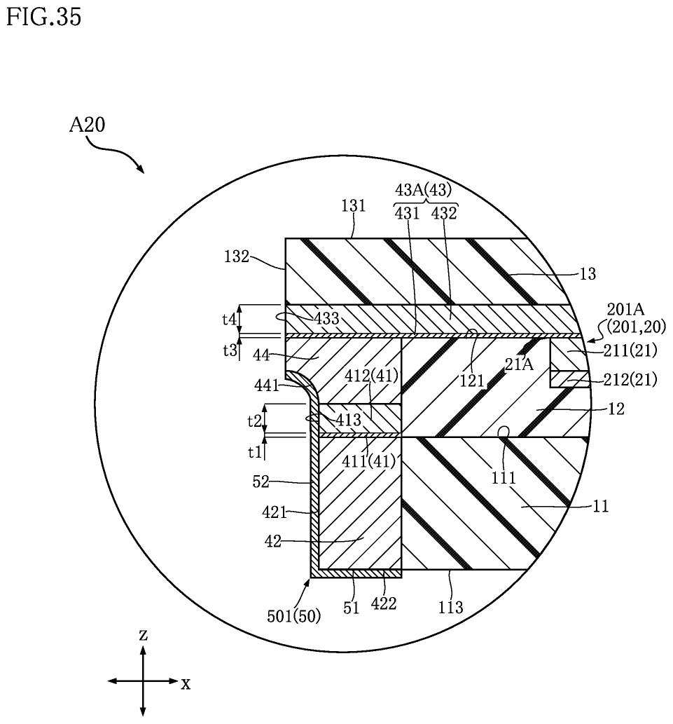

With reference to FIGS. 30 to 35, the following describes a semiconductor device A20 according to a second embodiment of the present disclosure. In these figures, components that are identical or similar to those of the semiconductor device A10 described above are given the same reference numerals, and descriptions of such components are omitted to avoid redundancy. For the convenience of description, FIG. 30 shows the second resin layer 12, the third resin layer 13, and the second wiring layers 43 as transparent. In FIG. 30, the third resin layer 13 is indicated by an imaginary line.

The semiconductor device A20 differs from the semiconductor device A10 described above in the configurations of the first resin layer 11, the second resin layer 12, and the terminals 50.

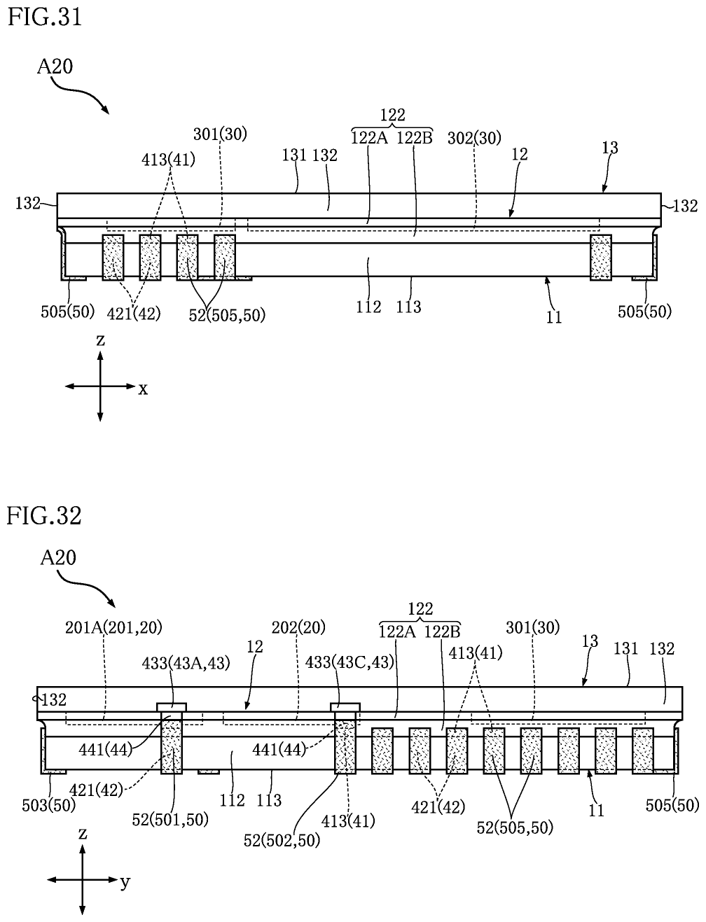

As shown in FIG. 30, the first lateral surface 112 of the first resin layer 11 is at a more inward location of the semiconductor device A20 than the third lateral surface 132 of the third resin layer 13 as viewed in the thickness direction z. As shown in FIGS. 31 and 32, the second lateral surface 122 of the second resin layer 12 includes a first region 122A and a second region 122B. The first region 122A is adjacent to the third lateral surface 132 in the thickness direction z and flush with the third lateral surface 132. The second region 122B is located between the first region 122A and the first lateral surface 112 in the thickness direction z. As viewed in the thickness direction z, the second region 122B is at a more inward location of the semiconductor device A20 than the first region 122A.

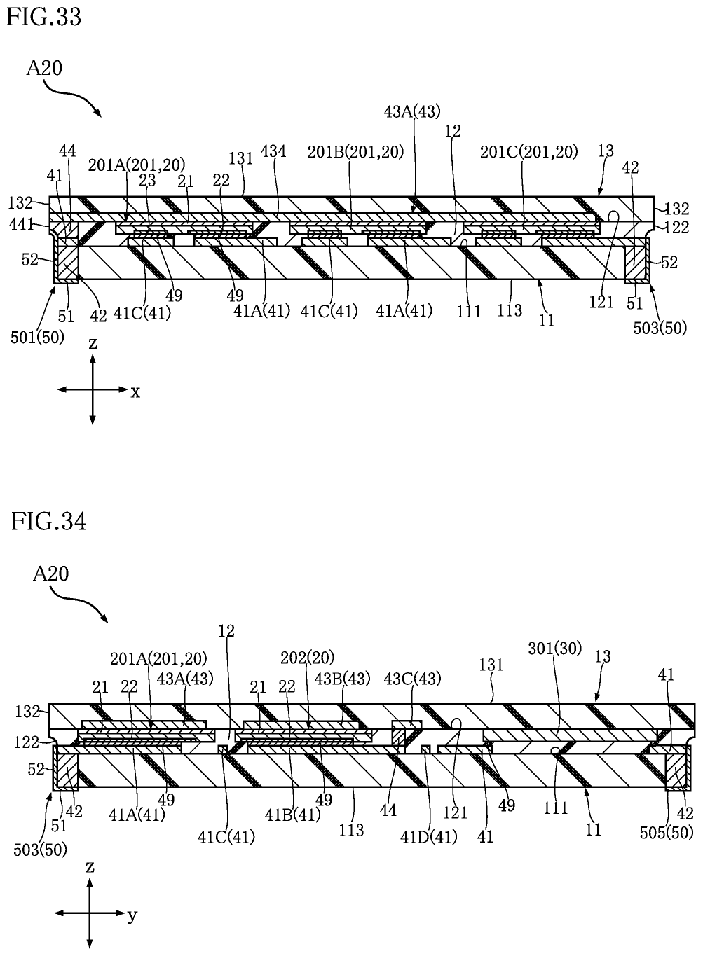

As shown in FIGS. 33 to 35, each terminal 50 includes a bottom part 51 and a lateral part 52. The bottom part 51 is located on the side opposite the first wiring layers 41 in the thickness direction z with the first pillar wiring layers 42 interposed therebetween. The bottom part 51 covers the reverse surface 422 of a first pillar wiring layer 42. The lateral part 52 extends from the bottom part 51 in the thickness direction z. The lateral part 52 covers the second end face 421 of a first pillar wiring layer 42 and the first end face 413 of a first wiring layer 41. The plurality of terminals 50 include a first terminal 501 and a second terminal 502 each having a lateral part 52 that additionally covers the fourth end face 441 of a relevant second pillar wiring layer 44.

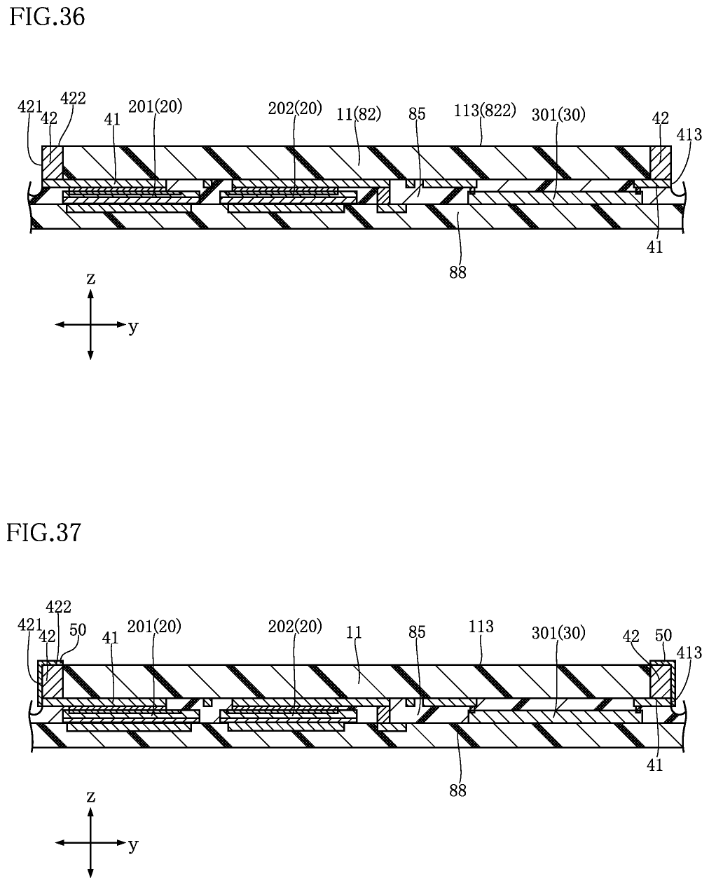

Next, an example of a method of manufacturing the semiconductor device A20 will be described with reference to FIGS. 36 and 37. Note that the sections shown in FIGS. 36 and 37 are taken along the same line as the section shown in in FIG. 34.

First, the manufacturing steps similar to those for the semiconductor device A10 are performed up to the step of forming the third resin layer 88 as shown in FIG. 27. Then, as shown in FIG. 36, the method of this embodiment proceeds to forming trenches recessed from the bottom surface 822 of the first resin layer 82 by removing portions of the first resin layer 82 and the second resin layer 85 along the grid lines that are parallel to the first direction x and the second direction y. The trenches may be formed by using a dicing blade, for example. In this way, the first resin layer 82 is finished as the first resin layer 11 of the semiconductor device A20. In addition, each first pillar wiring layer 42 is now formed with a second end face 421. At least one of the first wiring layers 41 has a first end face 413 exposed from the second resin layer 85. The trenches are formed to a depth at which the first resin layer 82 is completely cut through but to a depth not reaching the third resin layer 88.

Subsequently, as shown in FIG. 37, the method proceeds to forming a plurality of terminals 50 covering the reverse surfaces 422 of the first pillar wiring layers 42 exposed from the reverse surface of the first rein layer 11 and also covering the second end faces 421 of the first pillar wiring layers 42 exposed from the first resin layer 11. The terminals 50 are formed by electroless plating. Each terminal 50 thus formed also covers the first end face 413 of a first wiring layer 41 exposed from the second resin layer 85.

Subsequently, the method proceeds to the step similar to that shown in FIG. 29, including attaching a tape 89 to the surface of the third resin layer 88 facing in the thickness direction z, and cutting the second resin layer 85 and the third resin layer 88 along the grid lines that are parallel to the first direction x and the second direction y. The cutting lines are determined to coincide with the trenches formed in a grid pattern. Through the steps described above, the semiconductor device A20 is obtained.

Next, the operation and effect of the semiconductor device A20 will be described.

The semiconductor device A20 includes: a first wiring layer 41 facing a first obverse surface 111 of a first resin layer 11; a semiconductor element 20 having a semiconductor layer 21 and an electrode (a first electrode 22); a second resin layer 12 covering a portion of the semiconductor element 20; and a second wiring layer 43 facing a second obverse surface 121 of the second resin layer 12. The electrode of the semiconductor element 20 is electrically bonded to the first wiring layer 41. The second wiring layer 43 is in contact with the semiconductor layer 21 and electrically connected to the semiconductor layer 21. The second wiring layer 43 extends across the outer edge 21A of the semiconductor layer 21 as viewed in the thickness direction z. The present embodiment can therefore reduce the size and the parasitic resistance of the semiconductor device A20. In addition, the semiconductor device A20 is similar to the semiconductor device A10 in some configurations, and thus achieves the same effect as the semiconductor device A10 achieved by such configurations.

In the semiconductor device A20, each terminal 50 has a bottom part 51 and a lateral part 52. With this configuration, in the process of mounting the semiconductor device A20 onto a wiring board, molten solder will adhere to the lateral part 52 and helps to form solder fillet. This improves the bonding strength of the semiconductor device A20 to the wiring board. In addition, solder adhering to the lateral part 52 is readily visible and hence enables visually inspection of the bonding of the semiconductor device A20 to the wiring board.

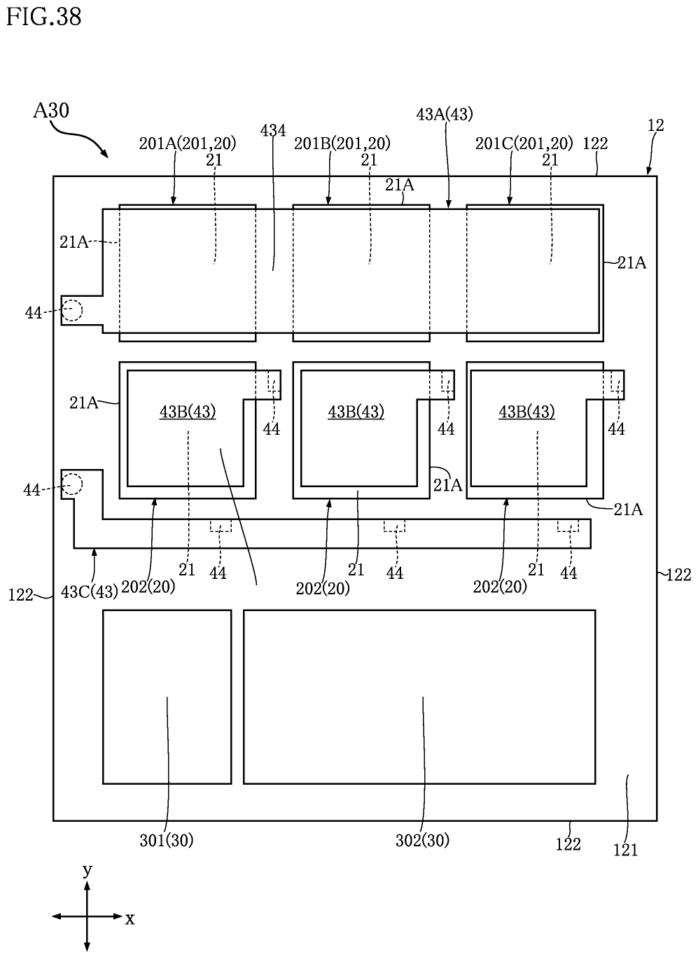

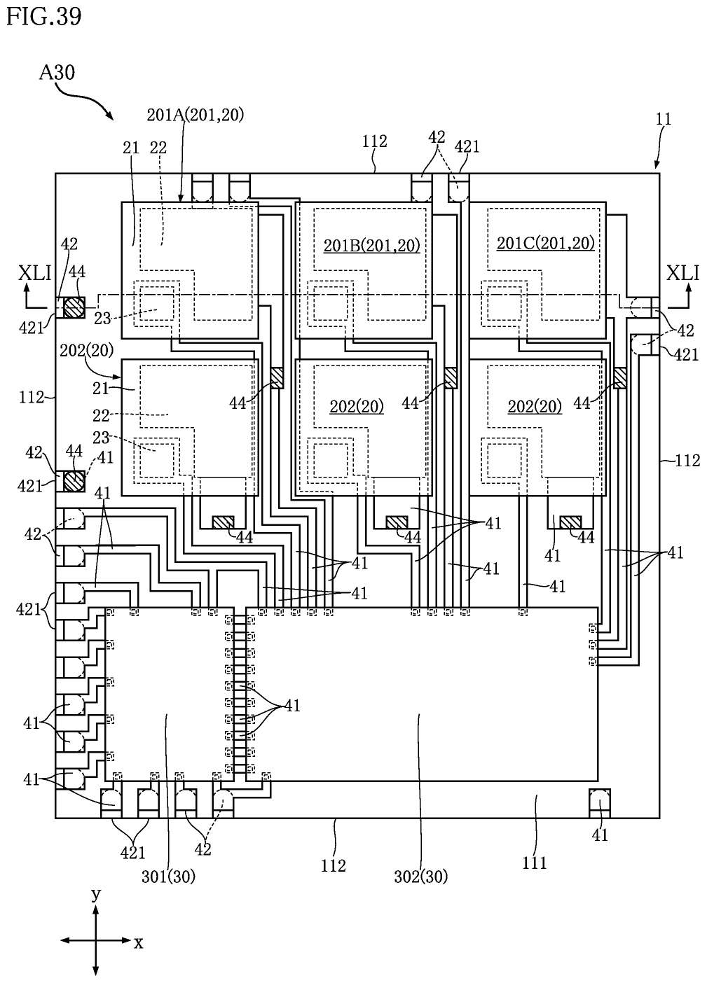

With reference to FIGS. 38 to 41, the following describes a semiconductor device A30 according to a third embodiment of the present disclosure. In these figures, components that are identical or similar to those of the semiconductor device A10 described above are given the same reference numerals, and descriptions of such components are omitted to avoid redundancy. For the convenience of description, FIG. 38 shows the third resin layer 13 as transparent. FIG. 39 shows the second resin layer 12 and the second wiring layers 43 as transparent, in addition to the third resin layer 13 shown as transparent in FIG. 38.

The semiconductor device A30 differs from the semiconductor device A10 described above in the configurations of the first wiring layers 41, the second wiring layers 43, and the second pillar wiring layers 44.

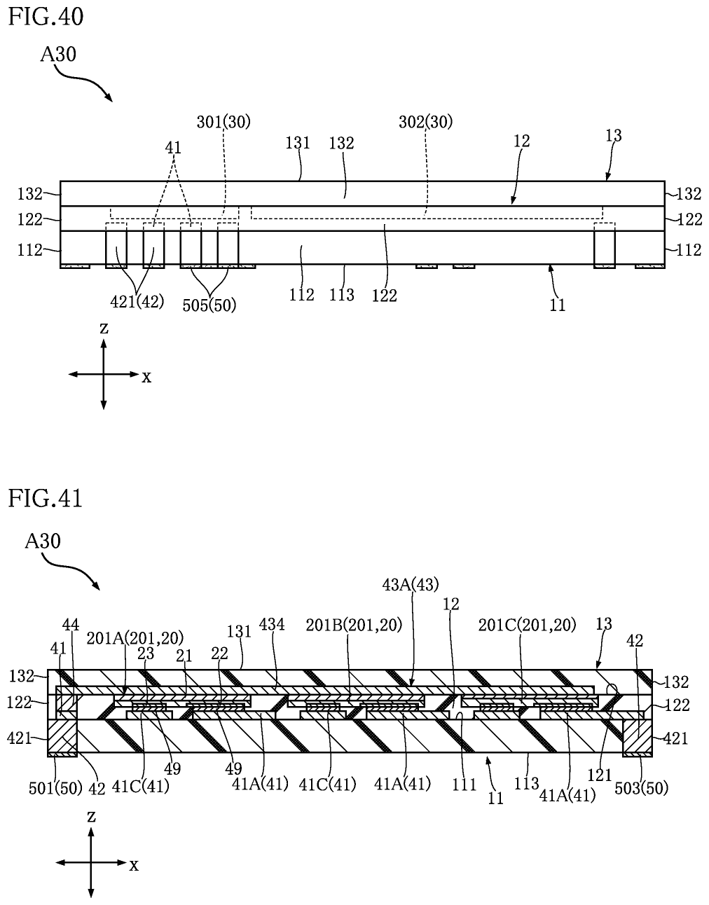

As shown in FIG. 39, the first wiring layers 41 and the second pillar wiring layers 44 of the semiconductor device A30 are located inside the outer edge of the first obverse surface 111 of the first resin layer 11 as viewed in thickness direction z. That is, as shown in FIGS. 40 and 41, the first wiring layers 41 and the second pillar wiring layers 44 are not exposed from the second lateral surface 122 of the second resin layer 12.

As shown in FIG. 38, the second wiring layers 43 of the semiconductor device A30 are located inside the outer edge of the second obverse surface 121 of the second resin layer 12 as viewed in the thickness direction z. That is, as shown in FIGS. 40 and 41, the second wiring layers 43 are not exposed from the third lateral surface 132 of the third resin layer 13.

Next, the operation and effect of the semiconductor device A30 will be described.

The semiconductor device A30 includes: a first wiring layer 41 facing a first obverse surface 111 of a first resin layer 11; a semiconductor element 20 having a semiconductor layer 21 and an electrode (a first electrode 22); a second resin layer 12 covering a portion of the semiconductor element 20; and a second wiring layer 43 facing a second obverse surface 121 of the second resin layer 12. The electrode of the semiconductor element 20 is electrically bonded to the first wiring layer 41. The second wiring layer 43 is in contact with the semiconductor layer 21 and electrically connected to the semiconductor layer 21. The second wiring layer 43 extends across the outer edge 21A of the semiconductor layer 21 as viewed in the thickness direction z. The present embodiment can therefore reduce the size and the parasitic resistance of the semiconductor device A30. The semiconductor device A30 is similar to the semiconductor device A10 in some configurations, and thus achieves the same effect as the semiconductor device A10 achieved by such configurations.

The first wiring layer 41 and the second pillar wiring layer 44 of the semiconductor device A30 are not exposed from the second lateral surface 122 of the second resin layer 12. In addition, the second wiring layer 43 is not exposed from the third lateral surface 132 of the third resin layer 13. Since the first wiring layer 41, the second wiring layer 43, and the second pillar wiring layer 44 are not exposed to the outside, the first pillar wiring layer 42 and the terminal 50 are the only metal layers exposed to the outside of the semiconductor device A30. This configuration is effective for improving the dielectric strength of the semiconductor device A30.

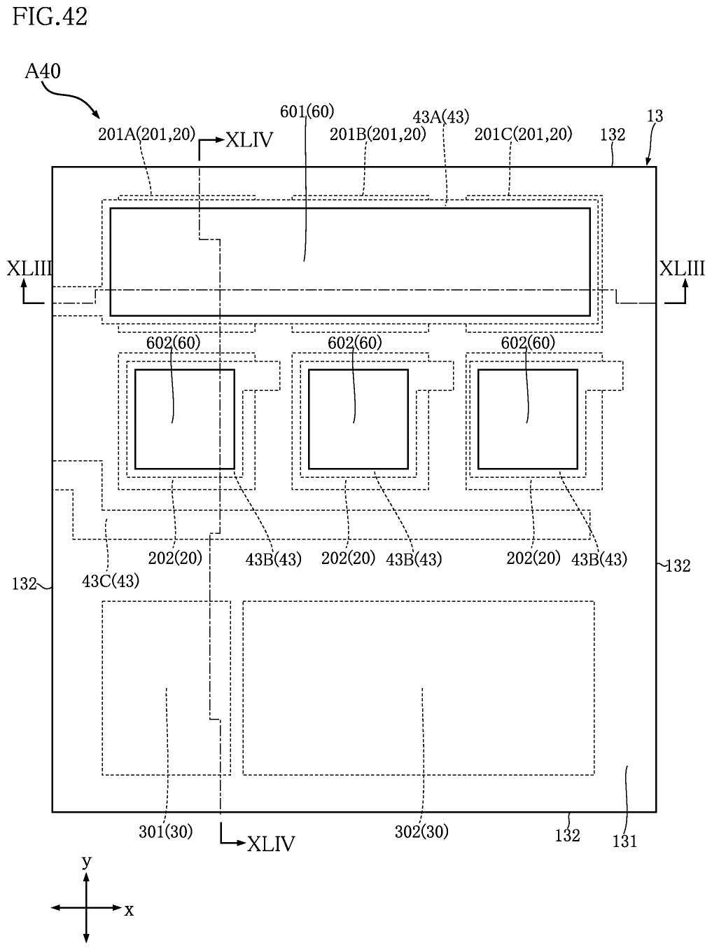

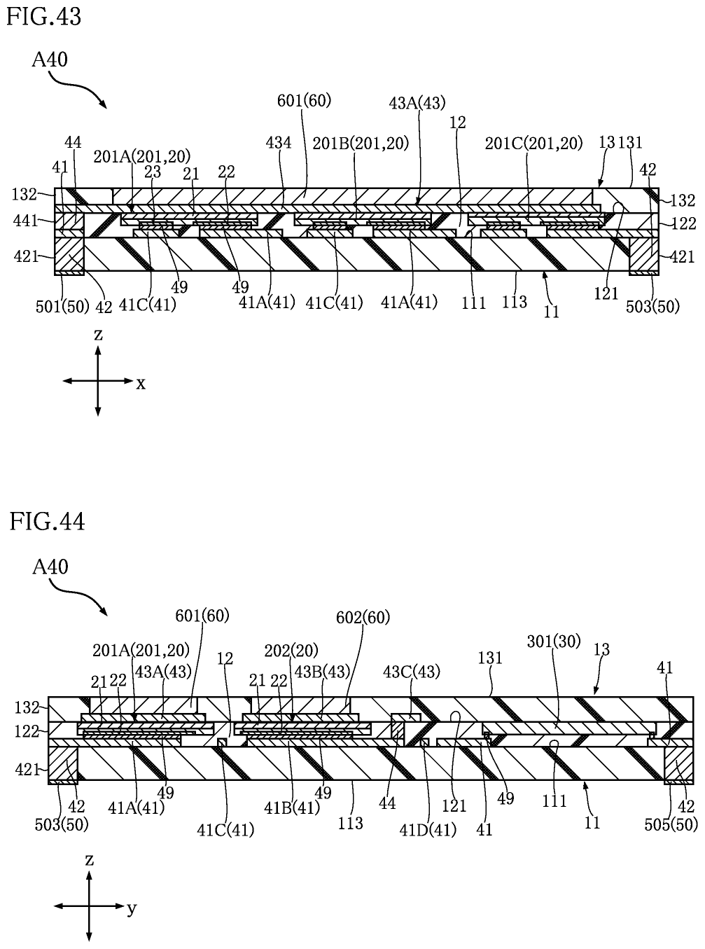

With reference to FIGS. 42 to 44, the following describes a semiconductor device A40 according to a fourth embodiment of the present disclosure. In these figures, components that are identical or similar to those of the semiconductor device A10 described above are given the same reference numerals, and descriptions of such components are omitted to avoid redundancy. For the convenience of description, FIG. 42 shows the third resin layer 13 as transparent.

Unlike the semiconductor device A10 described above, the semiconductor device A40 additionally includes a heat dissipating layer 60.

As shown in FIGS. 42 to 44, the semiconductor device A40 includes a heat dissipating layer 60. The heat dissipating layer 60 is located on the side opposite the second resin layer 12 in the thickness direction z with the second wiring layers 43 interposed therebetween. The heat dissipating layer 60 is in contact with the second wiring layers 43 and the third resin layer 13. The heat dissipating layer 60 has a surface facing in the thickness direction z and exposed from the third obverse surface 131 of the third resin layer 13. The surface is flush with the third obverse surface 131. The heat dissipating layer 60 contains copper, for example.

As shown in FIG. 42, the heat dissipating layer 60 includes a first heat dissipating layer 601 and a plurality of second heat dissipating layers 602. The first heat dissipating layer 601 is disposed in contact with the first input wiring part 43A. The first heat dissipating layer 601 overlaps with the group of high-voltage elements 201 and the first output wiring parts 41A as viewed in the thickness direction z. The second heat dissipating layers 602 are disposed in contact with the second input wiring parts 43B. Each second heat dissipating layer 602 overlaps with a semiconductor element of the group of low-voltage elements 202 and a second output wiring part 41B as viewed in the thickness direction z.

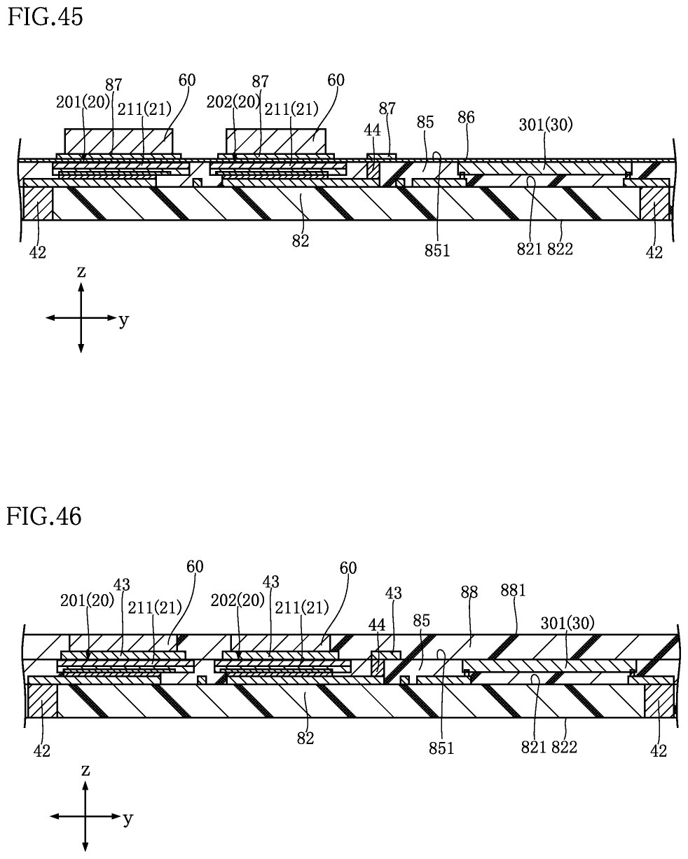

Next, an example of a method of manufacturing the semiconductor device A40 will be described with reference to FIGS. 45 and 46. Note that the sections shown in FIGS. 45 and 46 are taken along the same line as the section shown in in FIG. 44.

First, the manufacturing steps similar to those for the semiconductor device A10 are performed up to the step of forming the second plating layers 87 as shown in FIG. 26. Then, as shown in FIG. 45, the method of this embodiment proceeds to forming a heat dissipating layer 60 in contact with the second plating layers 87. The heat dissipating layer 60 is formed by lithography patterning of the second underlying layer 86 and the second plating layers 87 and subsequent electroplating using the second underlying layer 86 and the second plating layers 87 as conductive paths.

Subsequently, as shown in FIG. 46, the method proceeds to removing portions of the second underlying layer 86 not coated with the second plating layers 87. The second underlying layer 86 is removed by wet etching using a mixture solution of sulfuric acid and hydrogen peroxide. As a result, the second wiring layers 43 are formed. Subsequently, the method proceeds to forming a third resin layer 88 that covers the second wiring layers 43 and a portion of the heat dissipating layer 60. The third resin layer 88 is formed by compression molding as a layer covering all portions of the heat dissipating layer 60. Subsequently, the method proceeds to removing a portion of the third resin layer 88 and a portion of the heat dissipating layer 60 by grinding. Note that grinding is applied to the side away from the second resin layer 82 in the thickness direction z. As a result, the third resin layer 88 is formed with the third obverse surface 881 facing in the thickness direction z. The third obverse surface 881 corresponds to the third obverse surface 131 of the third resin layer 13 of the semiconductor device A40. The upper surfaces of the heat dissipating layer 60 is exposed from the third obverse surface 881.

Subsequently, the manufacturing steps similar to those shown in FIGS. 28 and 29 for the semiconductor device A10 are performed, and then the semiconductor device A40 is obtained.

Next, the operation and effect of the semiconductor device A40 will be described.

The semiconductor device A40 includes: a first wiring layer 41 facing a first obverse surface 111 of a first resin layer 11; a semiconductor element 20 having a semiconductor layer 21 and an electrode (a first electrode 22) ; a second resin layer 12 covering a portion of the semiconductor element 20; and a second wiring layer 43 facing a second obverse surface 121 of the second resin layer 12. The electrode of the semiconductor element 20 is electrically bonded to the first wiring layer 41. The second wiring layer 43 is in contact with the semiconductor layer 21 and electrically connected to the semiconductor layer 21. The second wiring layer 43 extends across the outer edge 21A of the semiconductor layer 21 as viewed in the thickness direction z. The present embodiment can therefore reduce the size and the parasitic resistance of the semiconductor device A40. The semiconductor device A40 is similar to the semiconductor device A10 in some configurations, and thus achieves the same effect as the semiconductor device A10 achieved by such configurations.

The semiconductor device A40 additionally includes a heat dissipating layer 60. The heat dissipating layer 60 is in contact with the third resin layer 13 and the second wiring layers 43 and is exposed from the third resin layer 13. This configuration allows heat generated by the semiconductor elements 20 during operation of the semiconductor device A40 to be efficiently released to the outside through the second wiring layers 43 and the heat dissipating layer 60. Preferably, the heat dissipating layer 60 is disposed to overlap with the semiconductor elements 20 as viewed in the thickness direction z for efficient heat generation.

The present disclosure is not limited to the embodiments described above. Various modifications in design may be made freely in the specific structure of each part of the present disclosure.

The present disclosure includes embodiments described in the following clauses.

Clause 1.

A semiconductor device comprising:
a first resin layer including a first obverse surface facing in a thickness direction;
a first wiring layer facing the first obverse surface;
a semiconductor element including a semiconductor layer, and an electrode electrically connected to the semiconductor layer and facing the first obverse surface, the electrode being electrically bonded to the first wiring layer;
a second resin layer including a second obverse surface facing a same side as the first obverse surface in the thickness direction, the second resin layer covering a portion of the semiconductor element; and
a second wiring layer facing the second obverse surface and electrically connected to the semiconductor layer,
wherein the second wiring layer is in contact with the semiconductor layer, and
the second wiring layer extends across an outer edge of the semiconductor layer as viewed in the thickness direction.

Clause 2.

The semiconductor device according to Clause 1, wherein the second wiring layer is in contact with the second obverse surface.

Clause 3.

The semiconductor device according to Clause 2, wherein the semiconductor layer includes a first layer and a second layer,
the first layer is located on a side opposite the electrode in the thickness direction with the second layer interposed therebetween, and
the second wiring layer is in contact with the first layer.

Clause 4.

The semiconductor device according to Clause 3, wherein the first layer is flush with the second obverse surface.

Clause 5.

The semiconductor device according to Clause 3 or 4, wherein the second wiring layer includes a first conductive layer in contact with the second obverse surface and the first layer, and a second conductive layer stacked on the first conductive layer, and
the second conductive layer has a greater thickness than the first conductive layer.

Clause 6.

The semiconductor device according to Clause 5, wherein the first conductive layer contains nickel.

Clause 7.

The semiconductor device according to Clause 5 or 6, wherein the first conductive layer includes a silicide layer in contact with the first layer.

Clause 8.

The semiconductor device according to any one of Clauses 2 to 7, wherein the second resin layer covers at least a portion of the first wiring layer.

Clause 9.

The semiconductor device according to Clause 8, wherein the first wiring layer is in contact with the first obverse surface.

Clause 10.

The semiconductor device according to Clause 9, further comprising a first pillar wiring layer embedded in the first resin layer,
wherein the first pillar wiring layer is in contact with the first wiring layer.

Clause 11.

The semiconductor device according to Clause 10, further comprising a second pillar wiring layer embedded in the second resin layer,
wherein the second pillar wiring layer is in contact with the first wiring layer and the second wiring layer.

Clause 12.

The semiconductor device according to Clause 11, further comprising a terminal in contact with the first pillar wiring layer,
wherein the terminal is exposed from the first resin layer.

Clause 13.

The semiconductor device according to Clause 12, wherein the terminal includes a bottom part and a lateral part,
the bottom part is located on a side opposite the first wiring layer in the thickness direction with the first pillar wiring layer interposed therebetween, and
the lateral part extends from the bottom part in the thickness direction.

Clause 14.

The semiconductor device according to any one of Clauses 8 to 13, further comprising a third resin layer facing the second obverse surface,
wherein the third resin layer covers at least a portion of the second wiring layer.

Clause 15.

The semiconductor device according to Clause 14, further comprising a heat dissipating layer located on a side opposite the second resin layer in the thickness direction with the second wiring layer interposed therebetween,
wherein the heat dissipating layer is in contact with the second wiring layer and the third resin layer and is exposed from the third resin layer.

Clause 16.

The semiconductor device according to any one of Clauses 1 to 15, wherein the second wiring layer includes a strip part extending in a first direction orthogonal to the thickness direction.

Clause 17.

The semiconductor device according to Clause 16, wherein the semiconductor element includes a first element and a second element spaced apart from each other in the first direction, and
the strip part includes a portion located between the first element and the second element in as viewed in the thickness direction.

Clause 18.

A method for manufacturing a semiconductor device, the method comprising:
forming a first resin layer including a first obverse surface facing in a thickness direction;
forming a first wiring layer facing the first obverse surface;
electrically bonding a semiconductor element to the first wiring layer;
forming a second resin layer that includes a second obverse surface facing a same side as the first obverse surface in the thickness direction and that covers a portion of the semiconductor element; and
forming a second wiring layer facing the second obverse surface and electrically connected to the semiconductor element,
wherein the semiconductor element includes a semiconductor layer, and an electrode electrically connected to the semiconductor layer and facing the first obverse surface,
the electrically bonding the semiconductor element to the first wiring layer includes electrically bonding the electrode to the first wiring layer,
the forming the second resin layer includes removing a portion of the semiconductor element and a portion of the second resin layer to expose the semiconductor layer on the second obverse surface, and
the forming the second wiring layer includes forming the second wiring layer that extends across an outer edge of the semiconductor layer as viewed in the thickness direction and that is in contact with the semiconductor layer.

### REFERENCE NUMERALS

A10, A20, A30, A40: Semiconductor device
11: First resin layer 111: First obverse surface
112: First lateral surface 113: Bottom surface
12: Second resin layer 121: Second obverse surface
122: Second lateral surface 122A: First region
122B: Second region 13: Third resin layer
131: Third obverse surface 132: Third lateral surface
20: Semiconductor element 201: Group high-voltage elements
201A: First element 201B: Second element
201C: Third element 202: Group of low-voltage elements
21: Semiconductor layer 21A: Outer edge
211: First layer 212: Second layer
22: First electrode 23: Second electrode
30: IC 301: First IC 302: Second IC
41: First wiring layer 41A: First output wiring part
41B: Second output wiring part 41C: First gate wiring part
41D: Second gate wiring part 41E: Boot wiring part
411: First conductive layer 412: Second conductive layer
413: First end face 42: First pillar wiring layer
421: Second end face 422: Reverse surface
43: Second wiring layer 43A: First input wiring part
43B: Second input wiring part 43C: Ground wiring part
431: First conductive layer 432: Second conductive layer
433: Third end face 434: Strip part
44: Second pillar wiring layer 441: Fourth end face
49: Conductive bonding layer 50: Terminal
501: First terminal 502: Second terminal
503: Third terminal 504: Fourth terminal
505: Fifth terminal 51: Bottom part
52: Lateral part 60: Heat dissipating layer
601: First heat dissipating layer
602: Second heat dissipating layer
80: Base 81: First underlying layer
82: First resin layer 821: First obverse surface
83: Second underlying layer 84: First plating layer
85: Second resin layer 851: Second obverse surface
86: Third underlying layer 87: Second plating layer
88: Third resin layer 881: Third obverse surface
89: Tape t1, t2, t3, t4: Thickness
z: Thickness direction x: First direction
y: Second direction

1. A semiconductor device comprising:
a first resin layer including a first obverse surface facing in a thickness direction;
a first wiring layer facing the first obverse surface;
a semiconductor element including a semiconductor layer, and an electrode electrically connected to the semiconductor layer and facing the first obverse surface, the electrode being electrically bonded to the first wiring layer;
a second resin layer including a second obverse surface facing a same side as the first obverse surface in the thickness direction, the second resin layer covering a portion of the semiconductor element; and
a second wiring layer facing the second obverse surface and electrically connected to the semiconductor layer,
wherein the second wiring layer is in contact with the semiconductor layer, and
the second wiring layer extends across an outer edge of the semiconductor layer as viewed in the thickness direction.

2. The semiconductor device according to claim 1, wherein the second wiring layer is in contact with the second obverse surface.

3. The semiconductor device according to claim 2, wherein the semiconductor layer includes a first layer and a second layer,
the first layer is located on a side opposite the electrode in the thickness direction with the second layer interposed therebetween, and
the second wiring layer is in contact with the first layer.

4. The semiconductor device according to claim 3, wherein the first layer is flush with the second obverse surface.

5. The semiconductor device according to claim 3, wherein the second wiring layer includes a first conductive layer in contact with the second obverse surface and the first layer, and a second conductive layer stacked on the first conductive layer, and
the second conductive layer has a greater thickness than the first conductive layer.

6. The semiconductor device according to claim 5, wherein the first conductive layer contains nickel.

7. The semiconductor device according to claim 5, wherein the first conductive layer includes a silicide layer in contact with the first layer.

8. The semiconductor device according to claim 2, wherein the second resin layer covers at least a portion of the first wiring layer.

9. The semiconductor device according to claim 8, wherein the first wiring layer is in contact with the first obverse surface.

10. The semiconductor device according to claim 9, further comprising a first pillar wiring layer embedded in the first resin layer,
wherein the first pillar wiring layer is in contact with the first wiring layer.

11. The semiconductor device according to claim 10, further comprising a second pillar wiring layer embedded in the second resin layer,
wherein the second pillar wiring layer is in contact with the first wiring layer and the second wiring layer.

12. The semiconductor device according to claim 11, further comprising a terminal in contact with the first pillar wiring layer,
wherein the terminal is exposed from the first resin layer.

13. The semiconductor device according to claim 12, wherein the terminal includes a bottom part and a lateral part,
the bottom part is located on a side opposite the first wiring layer in the thickness direction with the first pillar wiring layer interposed therebetween, and
the lateral part extends from the bottom part in the thickness direction.

14. The semiconductor device according to claim 8, further comprising a third resin layer facing the second obverse surface,
wherein the third resin layer covers at least a portion of the second wiring layer.

15. The semiconductor device according to claim 14, further comprising a heat dissipating layer located on a side opposite the second resin layer in the thickness direction with the second wiring layer interposed therebetween,
wherein the heat dissipating layer is in contact with the second wiring layer and the third resin layer and is exposed from the third resin layer.

16. The semiconductor device according to claim 1, wherein the second wiring layer includes a strip part extending in a first direction orthogonal to the thickness direction.

17. The semiconductor device according to claim 16, wherein the semiconductor element includes a first element and a second element spaced apart from each other in the first direction, and
the strip part includes a portion located between the first element and the second element in as viewed in the thickness direction.

18. A method for manufacturing a semiconductor device, the method comprising:
forming a first resin layer including a first obverse surface facing in a thickness direction;
forming a first wiring layer facing the first obverse surface;
electrically bonding a semiconductor element to the first wiring layer;
forming a second resin layer that includes a second obverse surface facing a same side as the first obverse surface in the thickness direction and that covers a portion of the semiconductor element; and
forming a second wiring layer facing the second obverse surface and electrically connected to the semiconductor element,
wherein the semiconductor element includes a semiconductor layer, and an electrode electrically connected to the semiconductor layer and facing the first obverse surface,
the electrically bonding the semiconductor element to the first wiring layer includes electrically bonding the electrode to the first wiring layer,
the forming the second resin layer includes removing a portion of the semiconductor element and a portion of the second resin layer to expose the semiconductor layer on the second obverse surface, and
the forming the second wiring layer includes forming the second wiring layer that extends across an outer edge of the semiconductor layer as viewed in the thickness direction and that is in contact with the semiconductor layer.
